(19) United States
(12) Patent Application Publication
(10) Pub. No.: US 2021/0028381 A1
(43) Pub. Date: Jan. 28, 2021

(54) METHOD OF MANUFACTURING MULTILAYER PEROVSKITE STRUCTURE, AND MULTILAYER PEROVSKITE STRUCTURE AND SOLAR CELL MANUFACTURED USING THE SAME

(71) Applicants: Korea University Research and Business Foundation, Seoul (KR); Global Frontier Center for Multiscale Energy Systems, Seoul (KR); Seoul National University R&DB Foundation, Seoul (KR)

(72) Inventors: Jun Hong NOH, Seoul (KR); Man Soo CHOI, Seoul (KR); Seung Min LEE, Seoul (KR); Yeoun Woo JANG, Daejeon (KR); Chan Su MOON, Yongin-si (KR); Kyung Mun YEOM, Bucheon-si (KR); Kwang CHOI, Yongin-si (KR)

(73) Assignees: Korea University Research and Business Foundation, Seoul (KR); Global Frontier Center for Multiscale Energy Systems, Seoul (KR); Seoul National University R&DB Foundation, Seoul (KR)

(21) Appl. No.: 16/936,914

(22) Filed: Jul. 23, 2020

(30) Foreign Application Priority Data
Jul. 23, 2019 (KR) 10-2019-0089135

(51) Int. Cl. H01L 51/42; H01L 51/00

(52) U.S. Cl. CPC H01L 51/4226; H01L 51/0026

(57) ABSTRACT

The present disclosure discloses a method of manufacturing a multilayer perovskite structure, and a multilayer perovskite structure and solar cell manufactured using the same. The method of manufacturing a multilayer perovskite structure according to an embodiment of the present disclosure includes a step of forming a first perovskite layer using a compound including a first perovskite precursor on a base substrate; a step of forming a second perovskite layer using a compound including a second perovskite precursor on a donor substrate; and a step of laminating the first and second perovskite layers so that the first and second perovskite layers contact each other and then applying heat or pressure to form a multilayer perovskite structure.

### CROSS-REFERENCE TO RELATED APPLICATION

This application claims priority to Korean Patent Application No. 10-2019-0089135, filed on Jul. 23, 2019 in the Korean Intellectual Property Office, the disclosure of which is incorporated herein by reference.

### BACKGROUND OF THE DISCLOSURE

### Field of the Disclosure

The present disclosure relates to a method of manufacturing a multilayer perovskite structure, and a multilayer perovskite structure and solar cell manufactured using the same.

### Description of the Related Art

3-dimensional (3D) perovskite crystal structure materials such as CH₃NH₃PbI₃ and HC(NH₂)₂PbI₃ have high light conversion efficiency, and thus, have attracted great attention as a next-generation energy source. However, commercialization of 3-dimensional (3D) perovskite crystal structure materials is limited due to low thermal stability and poor moisture resistance thereof.

To solve these problems, planar 2-dimensional (2D) materials having a Ruddlesden-Popper structure or a Dion-Jacobson structure having high moisture resistance have been used, but use thereof is limited due to low light conversion efficiency thereof.

Accordingly, a method of dissolving a 2D-forming material in a halide state in a liquid solvent and applying the dissolved 2D-forming material to a 3D surface has been used to achieve the high light conversion efficiency of a 3D perovskite and the moisture stability of a 2 D material at the same time. Through this method, an efficiency of 20.5% may be achieved.

When using the method using a liquid solution, the surface of a 3D perovskite may be damaged, or a 2D material may be mixed with the 3D material, thus forming a complex structure.

An attempt was made to form a 2D material on the surface of a 3D perovskite using a thermal evaporation process, but there was a problem of forming a quasi-2D phase.

Conventional methods of manufacturing a perovskite structure include a method using thermal evaporation, a method of spraying a solution prepared by dissolving a material capable of forming a 2D perovskite in a solvent onto a precursor layer, such as a 3D halide or PbI₂, that has already been formed, and a method of forming a perovskite film using a solution prepared by dissolving a material capable of forming both 3D and 2D perovskites in a solvent.

In this case, the quasi-2D phase refers to a crystalline film, wherein the state thereof cannot be precisely defined as a 3D or 2D state, formed using a method of dissolving a precursor having a 2D structure in a solution capable of dissolving a lower layer and applying the precursor-containing solution or a method of spraying a solution prepared by dissolving a precursor having a 3D or 2D structure when a precursor for forming a 2D structure is used in combination with a perovskite material.

FIG. 1 is a cross-sectional view showing a multilayer perovskite structure according to the related art (Silvia G. Motti et al., 2019, Supporting information) in detail.

Referring to FIG. 1, in the multilayer perovskite structure manufactured by the related art described above, a quasi-2D region and a 3D region are formed on a quartz substrate, an FTO substrate, or an ITO substrate.

However, this method inevitably adversely affects the light conversion efficiency and electrical properties of a 3D perovskite.

That is, the related art has a problem that a 2D perovskite compound is not formed properly on a 3D perovskite compound.

In addition, the related art has poor reproducibility in terms of chemical composition ratios and cannot repeatedly obtain a material having a required composition.

In addition, an attempt has been made to perform surface modification by exposing the surface of a gaseous material, but this method has difficulty in securing reproducibility due to the flow characteristics of the gas.

All of the methods described above reduce the high light conversion efficiency of a 3D perovskite and electrical properties such as electric conductivity. Accordingly, these methods are contrary to the original purpose of applying additional thermal, chemical, and mechanical stability to existing high-efficiency light conversion materials.

To solve these problems, there is a need for a method that is highly reproducible and does not cause damage to a corresponding surface.

### RELATED ART DOCUMENTS

### Patent Documents

Korean Patent Application Publication No. 10-2018-0050190, “QUASI-2D PEROVSKITE FILM, LIGHT-EMITTING DEVICE AND SOLAR CELL INCLUDING THE SAME, AND METHOD OF MANUFACTURING THE SAME”

Korean Patent Application Publication No. 10-2018-0087296, “MATERIAL FOR FORMING 2D PEROVSKITE, LAMINATE, DEVICE, AND TRANSISTOR”

### SUMMARY OF THE DISCLOSURE

Therefore, the present disclosure has been made in view of the above problems, and it is an object of the present disclosure to provide a method of manufacturing a multilayer perovskite structure, and a multilayer perovskite structure and solar cell manufactured using the same. According to the present disclosure, an independent interface may be formed without mixing of materials by transferring a compound including a perovskite precursor of a zero-, one-, or two-dimensional structure onto a compound including a perovskite precursor of a three-dimensional structure through a process of applying heat or pressure. Thereby, a solid-phase multilayer perovskite structure without damage at a contact surface may be manufactured.

It is another object of the present disclosure to provide a method of manufacturing a multilayer perovskite structure, and a multilayer perovskite structure and solar cell manufactured using the same. According to the present disclosure, through a process of applying heat or pressure, the surface of a compound including a perovskite precursor of a three-dimensional structure may be modified with a compound including a perovskite precursor of a zero-, one-, or two-dimensional structure.

It is still another object of the present disclosure to provide a method of manufacturing a multilayer perovskite structure, and a multilayer perovskite structure and solar cell manufactured using the same. According to the present disclosure, a multilayer perovskite structure having improved light conversion efficiency and moisture stability may be manufactured, without damaging or mixing materials, using a compound including a perovskite precursor of a three-dimensional structure having excellent light conversion efficiency and a compound including a perovskite precursor of a two-dimensional structure having excellent moisture stability.

It is still another object of the present disclosure to provide a method of manufacturing a multilayer perovskite structure, and a multilayer perovskite structure and solar cell manufactured using the same. According to the present disclosure, by growing a compound including a perovskite precursor of a zero-, one-, or two-dimensional structure on a compound including a perovskite precursor of a three-dimensional structure and transferring the compound including a perovskite precursor of a zero-, one-, or two-dimensional structure onto the compound including a perovskite precursor of a three-dimensional structure, a multilayer perovskite structure having excellent reproducibility may be manufactured.

It is yet another object of the present disclosure to provide a method of manufacturing a multilayer perovskite structure, and a multilayer perovskite structure and solar cell manufactured using the same. According to the present disclosure, by transferring a compound including a perovskite precursor of a three-dimensional structure and a compound including a perovskite precursor of a zero-, one-, or two-dimensional structure by applying heat or pressure, a solar cell having improved open-circuit voltage may be manufactured.

In accordance with one aspect of the present disclosure, provided is a method of manufacturing a multilayer perovskite structure including forming a first perovskite layer using a compound including a first perovskite precursor on a base substrate; forming a second perovskite layer using a compound including a second perovskite precursor on a donor substrate; and laminating the first and second perovskite layers so that the first and second perovskite layers contact each other and then applying heat or pressure to form a multilayer perovskite structure.

According to the method of manufacturing a multilayer perovskite structure according to the present disclosure, the compound including the second perovskite precursor of the second perovskite layer may be grown on the first perovskite layer to form the multilayer perovskite structure.

According to the method of manufacturing a multilayer perovskite structure according to the present disclosure, the second perovskite layer may be transferred onto the first perovskite layer to form the multilayer perovskite structure.

According to the method of manufacturing a multilayer perovskite structure according to the present disclosure, the first perovskite precursor may be represented by Chemical Formula 1 below:

CMX₃, [Chemical Formula 1]

wherein C is an organic cation or a metal cation, M is a divalent metal cation, and X is a monovalent anion.

According to the method of manufacturing a multilayer perovskite structure according to the present disclosure, the second perovskite precursor may be represented by Chemical Formula 2 below:

(ANH₃)₂(RNH₃)ₙ₋₁MₙX₃ₙ₊₁, [Chemical Formula 2]

wherein A is an aryl group or an alkyl group, R is an organic cation or a metal cation, M is a divalent metal cation, X is a monovalent anion, and n is an integer of 1 or more.

According to the method of manufacturing a multilayer perovskite structure according to the present disclosure, when heat or pressure is applied to the multilayer perovskite structure, the compound including the second perovskite precursor may be grown in a horizontal direction.

According to the method of manufacturing a multilayer perovskite structure according to the present disclosure, the multilayer perovskite structure may be heat-treated at a temperature of 30° C. to 120° C.

According to the method of manufacturing a multilayer perovskite structure according to the present disclosure, a pressure of 1 MPa to 100 MPa may be applied to the multilayer perovskite structure.

According to the method of manufacturing a multilayer perovskite structure according to the present disclosure, heat or pressure may be applied to the multilayer perovskite structure for 1 second to 24 hours.

According to the method of manufacturing a multilayer perovskite structure according to the present disclosure, a growth thickness of the compound including the second perovskite precursor may be adjusted depending on heating temperature or heating time when the multilayer perovskite structure is heated.

According to the method of manufacturing a multilayer perovskite structure according to the present disclosure, a growth thickness of the compound including the second perovskite precursor may be 30 nm to 150 nm.

In accordance with another aspect of the present disclosure, provided is a multilayer perovskite structure including a base substrate; a first perovskite layer formed on the base substrate and formed of a compound including a first perovskite precursor; and a second perovskite layer formed on the first perovskite layer and formed of a compound including a second perovskite precursor, wherein an independent interface is formed while the first and second perovskite layers are in contact with each other.

According to the multilayer perovskite structure of the present disclosure, the compound including the second perovskite precursor of the second perovskite layer may be grown on the first perovskite layer to form the multilayer perovskite structure.

According to the multilayer perovskite structure of the present disclosure, the second perovskite layer may be transferred onto the first perovskite layer to form the multilayer perovskite structure.

According to the multilayer perovskite structure of the present disclosure, the first perovskite layer may be formed of the compound including the first perovskite precursor having a three-dimensional structure, and the second perovskite layer may be formed of the compound including the second perovskite precursor having any one of zero-, one-, and two-dimensional structures.

According to the multilayer perovskite structure of the present disclosure, a growth thickness of the compound including the second perovskite precursor may be 30 nm to 150 nm.

In accordance with yet another aspect of the present disclosure, provided is a solar cell including a base substrate; a first electrode formed on the base substrate; a first charge transport layer formed on the first electrode; a perovskite photoactive layer formed on the first charge transport layer; a second charge transport layer formed on the perovskite photoactive layer; and a second electrode formed on the second charge transport layer, wherein the perovskite photoactive layer includes a first perovskite layer and a second perovskite layer, and an independent interface is formed while the first and second perovskite layers are in contact with each other.

According to the solar cell of the present disclosure, the first perovskite layer may be formed of the compound including the first perovskite precursor having a three-dimensional structure, and the second perovskite layer may be formed of the compound including the second perovskite precursor having any one of zero-, one-, and two-dimensional structures.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a cross-sectional view showing a multilayer perovskite structure according to the prior art in detail;

FIG. 2 is a flowchart for explaining a method of manufacturing a multilayer perovskite structure according to an embodiment of the present disclosure;

FIG. 3 is a schematic diagram showing a process of manufacturing a multilayer perovskite structure according to an embodiment of the present disclosure;

FIG. 4 is a graph showing pressure and temperature conditions for manufacture of a multilayer perovskite structure according to an embodiment of the present disclosure;

FIG. 5 is a perspective view showing a multilayer perovskite structure according to an embodiment of the present disclosure in detail;

FIG. 6A is a scanning electron microscope (SEM) image showing the cross section of a multilayer perovskite structure according to an embodiment of the present disclosure, and FIG. 6B is a low-magnification scanning electron microscope (SEM) image showing the cross section of a multilayer perovskite structure according to an embodiment of the present disclosure;

FIG. 7 is a cross-sectional view showing a solar cell according to an embodiment of the present disclosure in detail;

FIG. 8A is a scanning electron microscope (SEM) image showing the surface of a first perovskite layer included in a multilayer perovskite structure according to an embodiment of the present disclosure;

FIG. 8B is an SEM image showing the surface of a second perovskite layer grown on a multilayer perovskite structure according to an embodiment of the present disclosure;

FIG. 9 includes graphs showing x-ray diffraction (XRD) data depending on processing conditions for a multilayer perovskite structure according to an embodiment of the present disclosure;

FIG. 10 is an image showing color change over time when a multilayer perovskite structure according to an embodiment of the present disclosure is exposed to humidity;

FIG. 11 is a graph showing the current-voltage curves of a multilayer perovskite solar cell according to an embodiment of the present disclosure;

FIG. 12A is a graph showing the current-voltage curves of a multilayer perovskite solar cell according to an embodiment of the present disclosure;

FIG. 12B shows a power conversion efficiency certificate for a multilayer perovskite solar cell according to an embodiment of the present disclosure issued by an accredited certification body;

FIG. 13 is a graph showing the long-term efficiency of a multilayer perovskite solar cell according to an embodiment of the present disclosure; and

FIG. 14 is a graph showing solar cell efficiency depending on the moisture stability of a solar cell according to an embodiment of the present disclosure.

FIG. 15 is a graph showing the solar cell efficiency depending on the moisture stability of the solar cells according to Example 10 and Comparative Example 6.

FIG. 16 is a graph showing solar cell efficiency depending on the moisture stability of the solar cell according to Example 9.

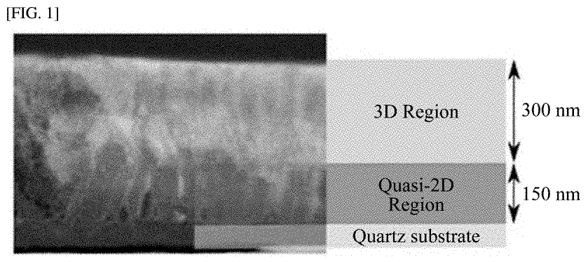

### DETAILED DESCRIPTION OF THE DISCLOSURE

The present disclosure will now be described more fully with reference to the accompanying drawings and contents disclosed in the drawings. However, the present disclosure should not be construed as limited to the exemplary embodiments described herein.

The terms used in the present specification are used to explain a specific exemplary embodiment and not to limit the present inventive concept. Thus, the expression of singularity in the present specification includes the expression of plurality unless clearly specified otherwise in context. It will be further understood that the terms “comprise” and/or “comprising”, when used in this specification, specify the presence of stated components, steps, operations, and/or elements, but do not preclude the presence or addition of one or more other components, steps, operations, and/or elements thereof.

It should not be understood that arbitrary aspects or designs disclosed in “embodiments”, “examples”, “aspects”, etc. used in the specification are more satisfactory or advantageous than other aspects or designs.

In addition, the expression “or” means “inclusive or” rather than “exclusive or”. That is, unless otherwise mentioned or clearly inferred from context, the expression “x uses a or b” means any one of natural inclusive permutations.

In addition, as used in the description of the disclosure and the appended claims, the singular form “a” or “an” is intended to include the plural forms as well, unless context clearly indicates otherwise.

Although terms used in the specification are selected from terms generally used in related technical fields, other terms may be used according to technical development and/or due to change, practices, priorities of technicians, etc. Therefore, it should not be understood that terms used below limit the technical spirit of the present disclosure, and it should be understood that the terms are exemplified to describe embodiments of the present disclosure.

Also, some of the terms used herein may be arbitrarily chosen by the present applicant. In this case, these terms are defined in detail below. Accordingly, the specific terms used herein should be understood based on the unique meanings thereof and the whole context of the present disclosure.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In addition, in the following description of the present disclosure, a detailed description of known functions and configurations incorporated herein will be omitted when it may make the subject matter of the present disclosure unclear. The terms used in the specification are defined in consideration of functions used in the present disclosure, and can be changed according to the intent or conventionally used methods of clients, operators, and users. Accordingly, definitions of the terms should be understood on the basis of the entire description of the present specification.

According to a method of manufacturing a multilayer perovskite structure according to the present disclosure, a multilayer structure is manufactured using perovskite compounds having different crystal structures and compositions. Specifically, the present disclosure relates to a method of manufacturing a perovskite structure of a solid-phase multilayer structure by applying heat or pressure to the perovskite compounds, wherein the contact surface of the multilayer structure is not damaged.

By using the method of the present disclosure, a multilayer perovskite structure may be manufactured while maintaining or strengthening the properties of the perovskite compounds having different crystal structures and compositions.

In the multilayer perovskite structure manufactured in this way, the perovskite compounds having different crystal structures and compositions are laminated. Thus, a surface may be modified.

In addition, by transferring the perovskite compounds having different crystal structures and compositions, a multilayer perovskite structure having improved thermal, electrical, and mechanical stability may be manufactured.

In addition, through surface modification due to formation of a thin film material, a multilayer perovskite structure having improved surface curvature and electrical properties may be manufactured.

A solar cell may be manufactured using the multilayer perovskite structure according to an embodiment of the present disclosure.

The solar cell according to an embodiment of the present disclosure is provided with a perovskite photoactive layer including perovskite compounds. In this case, the perovskite photoactive layer may be formed using the method of manufacturing a multilayer perovskite structure according to an embodiment of the present disclosure.

Hereinafter, the method of manufacturing a multilayer perovskite structure, and the multilayer perovskite structure and solar cell manufactured using the same according to embodiments of the present disclosure will be described in detail with reference to the accompanying drawings.

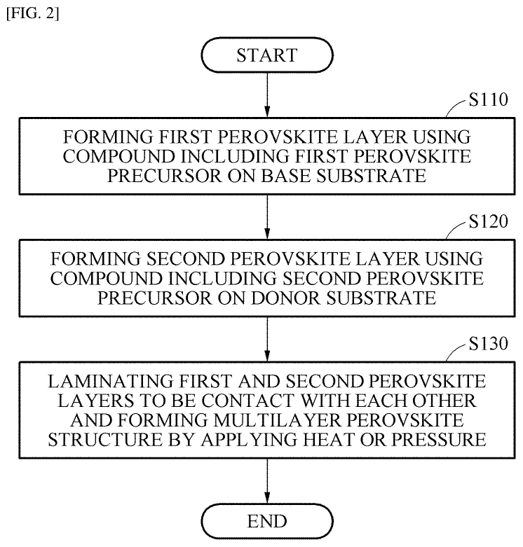

FIG. 2 is a flowchart for explaining a method of manufacturing a multilayer perovskite structure according to an embodiment of the present disclosure.

Referring to FIG. 2, the method of manufacturing a multilayer perovskite structure according to an embodiment of the present disclosure includes step S110 of forming a first perovskite layer using a compound including a first perovskite precursor on a base substrate, step S120 of forming a second perovskite layer using a compound including a second perovskite precursor on a donor substrate, and step S130 of laminating the first and second perovskite layers so that the first and second perovskite layers contact each other and then applying heat or pressure to form a multilayer perovskite structure.

In step S110, the compound including the first perovskite precursor prepared in a liquid form may be applied onto a base substrate 110, the compound prepared in a gaseous form may be deposited on the base substrate 110, or the compound prepared in a solid form may be transferred to the base substrate 110 to form a first perovskite layer 120, without being limited thereto.

The base substrate 110 is used to form the first perovskite layer 120, and an inorganic substrate or an organic substrate may be used as the base substrate 110.

In step S110, the base substrate 110 may be heat-treated before forming the first perovskite layer 120.

According to an embodiment, the base substrate 110 may be pre-heated at a predetermined temperature and then heat-treated or may be heat-treated after the compound including the first perovskite precursor to be described later is applied to the base substrate 110.

According to an embodiment, when the compound including the first perovskite precursor is prepared in a liquid form, the base substrate 110 is pre-heated at a predetermined temperature, and as a result, crystallization occurs as a solvent contained in a solution including the first perovskite precursor applied onto the base substrate 110 evaporates to form the solid-phase first perovskite layer 120.

The heat treatment temperature of the base substrate 110 may be set to 50° C. to 250° C. depending on the boiling point of a solvent contained in a solution including the first perovskite precursor, without being limited thereto.

Specifically, the rate of evaporation of the solvent may be adjusted depending on the heat treatment temperature of the base substrate 110. Thereby, the diameter of the crystal particles of the compound including the first perovskite precursor and the thickness of the first perovskite layer 120 may be adjusted.

However, when the base substrate 110 is heat-treated at an excessively high temperature, decomposition of the first perovskite precursor may occur. When the base substrate 110 is heat-treated at an excessively low temperature, the solvent may not evaporate, which makes formation of the first perovskite layer 120 difficult.

In step S110, the solution including the first perovskite precursor may be applied onto the base substrate 110 through spray coating, spin coating, ultra-spray coating, electrospinning coating, slot die coating, gravure coating, bar coating, roll coating, dip coating, shear coating, screen printing, inkjet printing, or nozzle printing, without being limited thereto.

An inorganic substrate or an organic substrate may be used as the base substrate 110 according to embodiments.

The inorganic substrate may be glass, quartz, Al₂O₃, SiC, Si, GaAs, or InP, without being limited thereto.

The organic substrate may be selected from Kapton foil, polyimide (PI), polyethersulfone (PES), polyacrylate (PAR), polyetherimide (PEI), polyethylene naphthalate (PEN), polyethylene terephthalate (PET), polyphenylene sulfide (PPS), polyarylate, polycarbonate (PC), polydimethylsiloxane (PDMS), cellulose triacetate (CTA), and cellulose acetate propionate (CAP), without being limited thereto.

According to an embodiment, the base substrate 110 may be any one of PEN or PET flexible substrates, ITO- or FTO-coated transparent substrates, carbon substrates, and metal fiber-coated substrates, without being limited thereto.

When an organic substrate is used as the base substrate 110, the flexibility of the multilayer perovskite structure 100 according to an embodiment of the present disclosure may be increased.

According to an embodiment, an inorganic or organic substrate of a transparent material through which light is transmitted is used as the base substrate 110. Accordingly, the multilayer perovskite structure 100 according to an embodiment of the present disclosure may be transparent.

The first perovskite precursor of the first perovskite layer 120 formed on the base substrate 110 may be represented by Chemical Formula 1 below:

CMX₃, [Chemical Formula 1]

wherein C is an organic cation or a metal cation, M is a divalent metal cation, and X is a monovalent anion.

Since C in Chemical Formula 1 is an organic cation, the first perovskite precursor may be an organic/inorganic hybrid perovskite compound.

When C is an organic cation, C may include at least one of (CH₃NH₃)⁺, (CH(NH₂)₂)⁺, and (CH₃CH₂NH₃)⁺.

According to an embodiment, when C is an organic cation, C may be a straight-chain or branched-chain alkyl group having 1 to 24 carbons, a straight-chain or branched-chain alkyl group having 1 to 24 carbons substituted with an amine group (—NH₃), a hydroxyl group (—OH), a cyano group (—CN), a halogen group, a nitro group (—NO), a methoxy group (—OCH₃), or an imidazolium group, or a combination thereof.

According to an embodiment, when C is a metal cation, C may be a cesium ion (Cs⁺) or a rubidium ion (Rb⁺), without being limited thereto.

The divalent metal cation M may include at least one of Pb²⁺, Cu²⁺, Ni²⁺, Co²⁺, Fe²⁺, Mn²⁺, Cr²⁺, Pd²⁺, Cd²⁺, Yb²⁺, Sn²⁺, and Ge²⁺, without being limited thereto.

The monovalent anion X may be a halide material and may include at least one of I⁻, Br⁻, Cl⁻, and F⁻.

For example, the first perovskite precursor may be CH₃NH₃PbI₃ or HC(NH₂)₂PbI₃.

The first perovskite precursor represented by Chemical Formula 1 may have a three-dimensional structure. Accordingly, the first perovskite layer 120 may include the first perovskite precursor having a three-dimensional structure.

Accordingly, the first perovskite layer 120 including the first perovskite precursor having a three-dimensional structure may have high light conversion efficiency due to the nature of the crystal structure of the first perovskite precursor.

According to an embodiment, the first perovskite precursor may be a mixed halide perovskite compound.

In this case, the mixed halide refers to a mixture obtained by mixing the above monovalent anions which are different kinds of halogen materials.

According to an embodiment, the first perovskite precursor may have a single structure, a double structure, or a triple structure.

When the first perovskite precursor has a single structure, the perovskite of Chemical Formula 1 has a three-dimensional single phase.

When the first perovskite precursor has a double structure, (A1)ₐ(M1)_{b}(X1)_{c} and (A2)ₐ(M2)_{b}(X2)_{c} are alternately laminated to form the first perovskite layer 120.

That is, when the first perovskite precursor has a double structure, lamination may be performed in the order of (A1)ₐ(M1)_{b}(X1)_{c}-(A2)ₐ(M2)_{b}(X2)_{c}-(A1)ₐ(M1)_{b}(X1)_{c}-(A2)ₐ(M2)_{b}(X2)_{c}-(A1)ₐ(M1)_{b}(X1)_{c}-(A2)ₐ(M2)_{b}(X2)_{c}- . . . to form the first perovskite layer 120.

In this case, in Chemical Formula (A1)ₐ(M1)_{b}(X1)_{c} and Chemical Formula (A2)ₐ(M2)_{b}(X2)_{c}, A1 and A2 are the same monovalent cation or different monovalent cations, M1 and M2 are the same divalent metal cation or different divalent metal cations, or the same trivalent metal cation or different trivalent metal cations, and X1 and X2 are the same monovalent anion or different monovalent anions. Here, one or more elements between A1, M1, X1 and A2, M2, X2 are different from each other.

When the first perovskite precursor has a triple structure, (A1)ₐ(M1)_{b}(X1)_{c}, (A2)ₐ(M2)_{b}(X2)_{c}, and (A3)ₐ(M3)_{b}(X3)_{c} may be alternately laminated to form the first perovskite layer 120.

In this case, A1, A2, and A3 are the same monovalent cation or different monovalent cations, M1, M2, and M3 are the same divalent metal cation or different divalent metal cations, or the same trivalent metal cation or different trivalent metal cations, and X1, X2, and X3 are the same monovalent anion or different monovalent anions. Here, one or more elements among A1, M1, X1; A2, M2, X2; and A3, M3, X3 are different from each other.

That is, when the perovskite compound has a triple structure, lamination may be performed in the order of (A1)ₐ(M1)_{b}(X1)_{c}-(A2)ₐ(M2)_{b}(X2)_{c}-(A3)ₐ(M3)_{b}(X3)_{c}-(A1)ₐ(M1)_{b}(X1)_{c}-(A2)ₐ(M2)_{b}(X2)_{c}-(A3)ₐ(M3)_{b}(X3)_{c}-(A1)ₐ(M1)_{b}(X1)_{c}-(A2)ₐ(M2)_{b}(X2)_{c}-(A3)ₐ(M3)_{b}(X3)_{c}- . . . to form a perovskite film.

According to an embodiment, the first perovskite layer 120 may be formed of the first perovskite precursor having a zero-dimensional structure such as a quantum dot, a one-dimensional fiber structure, a two-dimensional planar structure, or a three-dimensional structure.

In step S120, a donor substrate 130 is used to form a second perovskite layer 140, and may have the same properties as the above-described base substrate 110. Thus, repeated description thereof is omitted.

According to an embodiment, like the base substrate 110, the second perovskite layer 140 may be formed on the donor substrate 130 using the compound including the second perovskite precursor.

The compound including the second perovskite precursor prepared in a liquid form may be applied onto the donor substrate 130, the compound prepared in a gaseous form may be deposited on the donor substrate 130, or the compound prepared in a solid form may be transferred to the donor substrate 130 to form the second perovskite layer 140.

When the compound including the second perovskite precursor is prepared in a liquid form, the donor substrate 130 may be pre-heated before applying a solution including the second perovskite precursor.

According to an embodiment, the donor substrate 130 may be an organic substrate or an inorganic substrate.

When an organic substrate is used as the donor substrate 130, flexibility may be imparted. Thus, in step S130, the donor substrate 130 may be easily separated from the second perovskite layer 140.

According to an embodiment, the donor substrate 130 may be any one of PEN or PET flexible substrates, ITO- or FTO-coated transparent substrates, carbon substrates, and metal fiber-coated substrates, without being limited thereto.

In step S120, the solution including the second perovskite precursor may be applied onto the donor substrate 130 through spray coating, spin coating, ultra-spray coating, electrospinning coating, slot die coating, gravure coating, bar coating, roll coating, dip coating, shear coating, screen printing, inkjet printing, or nozzle printing, without being limited thereto.

The second perovskite precursor included in the second perovskite layer 140 formed on the donor substrate 130 may be represented by Chemical Formula 2 below:

(ANH₃)₂(RNH₃)ₙ₋₁MₙX₃ₙ₊₁, [Chemical Formula 2]

wherein A is an aryl group or an alkyl group, R is an organic cation or a metal cation, M is a divalent metal cation, X is a monovalent anion, and n is an integer of 1 or more.

Like the first perovskite precursor, the second perovskite precursor may be an organic/inorganic hybrid perovskite compound.

When R is an organic cation, R may include at least one of (CH₃NH₃)⁺, (CH(NH₂)₂)⁺, and (CH₃CH₂NH₃)⁺, without being limited thereto.

According to an embodiment, R may be a straight-chain or branched-chain alkyl group having 1 to 24 carbons, a straight-chain or branched-chain alkyl group having 1 to 24 carbons substituted with an amine group (—NH₃), a hydroxyl group (—OH), a cyano group (—CN), a halogen group, a nitro group (—NO), a methoxy group (—OCH₃), or an imidazolium group, or a combination thereof.

When R is a metal cation, R may be a cesium ion (Cs⁺) or a rubidium ion (Rb⁺), without being limited thereto.

The divalent metal cation M may include at least one of Pb²⁺, Cu²⁺, Ni²⁺, Co²⁺, Fe²⁺, Mn²⁺, Cr²⁺, Pd²⁺, Cd²⁺, Yb²⁺, Sn²⁺, and Ge²⁺, without being limited thereto.

The monovalent anion X is a halide material, and may include at least one of I⁻, Br⁻, Cl⁻, and F⁻.

The second perovskite precursor represented by Chemical Formula 2 may have a zero-, one-, or two-dimensional structure, and thus the second perovskite layer 140 may include the compound including the second perovskite precursor having a zero-, one-, or two-dimensional structure.

The second perovskite precursor of a one-dimensional structure may have a fiber structure, and the second perovskite precursor of a two-dimensional structure may have a planar structure.

According to an embodiment, the second perovskite layer 140 may be formed on the donor substrate 130 using a compound including both the second perovskite precursor of a one-dimensional structure and the second perovskite precursor of a two-dimensional structure.

According to an embodiment, the second perovskite precursor having a zero-, one-, or two-dimensional structure may have a Ruddlesden-Popper structure.

The Ruddlesden-Popper structure is a structure of (A1)ₐ(M1)_{b}(X1)_{c}{(A2)ₐ(M2)_{b}(X2)_{c}}ₙ(A1)ₐ(M1)_{b}(X1)_{c}. In this case, n is a natural number.

According to an embodiment, the second perovskite layer 140 formed of the compound including the second perovskite precursor having a two-dimensional structure may have a structure in which a carbon chain protrudes.

Accordingly, the second perovskite layer 140 formed of the compound including the second perovskite precursor having a zero-, one-, or two-dimensional structure may have high moisture stability due to the nature of the crystal structure of the second perovskite precursor.

According to an embodiment, the second perovskite precursor may be a mixed halide perovskite compound.

According to an embodiment, the second perovskite layer may be formed of the compound including the second perovskite precursor having any one of a zero-dimensional structure, a one-dimensional fiber structure, a two-dimensional planar structure, and a three-dimensional structure.

In step S130, the first and second perovskite layers 120 and 140 may be laminated to contact each other.

Accordingly, the first perovskite layer 120 may be laminated on the base substrate 110, the second perovskite layer 140 may be laminated on the first perovskite layer 120, and the donor substrate 130 may be laminated on the second perovskite layer 140.

According to an embodiment, to manufacture a multilayer perovskite structure 100, the first and second perovskite layers 120 and 140 may be laminated to contact each other using a roll-to-roll process.

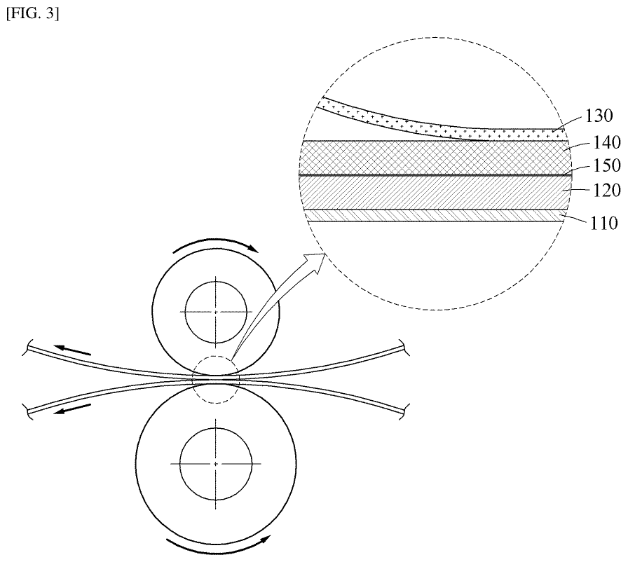

FIG. 3 is a schematic diagram showing a process of manufacturing a multilayer perovskite structure according to an embodiment of the present disclosure.

FIG. 3 is a schematic diagram showing a process of manufacturing the multilayer perovskite structure 100 through a roll-to-roll process.

Referring to FIG. 3, two rolls are placed on top and bottom, respectively. The donor substrate 130 on which the second perovskite layer 140 is formed is in contact with the roll located at the top, and the base substrate 110 on which the first perovskite layer 120 is formed is in contact with the roll located at the bottom.

In this case, to perform a roll-to-roll process, the base substrate 110 and the donor substrate 130 are preferably formed of flexible materials.

In addition, to perform a roll-to-roll process, the base substrate 110 on which the first perovskite layer 120 is formed and the donor substrate 130 on which the second perovskite layer 140 is formed may be pre-fabricated to have a large area.

As the base substrate 110 on which the first perovskite layer 120 is formed and the donor substrate 130 on which the second perovskite layer 140 is formed move as the rolls located at the top and the bottom rotate, the first perovskite layer 120 of the base substrate 110 and the second perovskite layer 140 of the donor substrate 130 may contact each other.

Referring to the enlarged image inserted in FIG. 3, as the second perovskite layer 140 is moved on the first perovskite layer 120 while the first and second perovskite layers 120 and 140 are in contact with each other, the first and second perovskite layers 120 and 140 are sequentially laminated on the base substrate 110, and the donor substrate 130 is separated from the second perovskite layer 140.

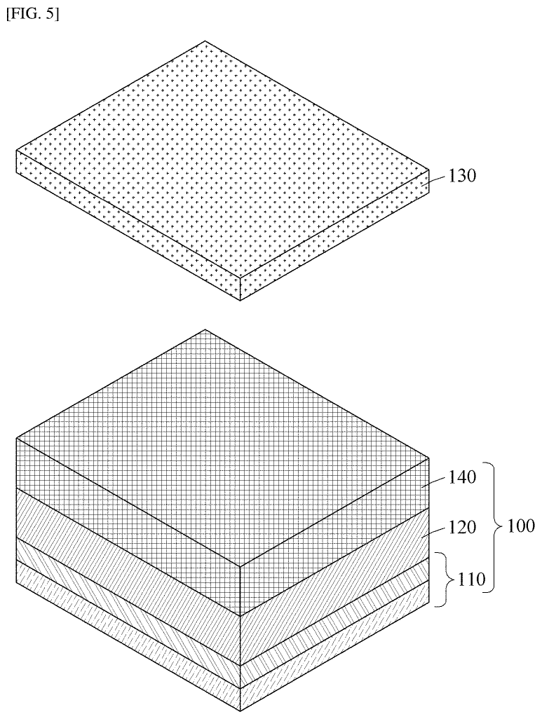

In this case, the second perovskite layer 140 laminated on the first perovskite layer 120 may form an independent interface 150 without mixing between a material forming the first perovskite layer and a material forming the second perovskite layer, and a solid-phase multilayer structure may be formed without damage at the contact surface between the first and second perovskite layers. Detailed description of the independent interface 150 will be described with reference to FIG. 5 to be described later.

Although not specifically shown in the enlarged image inserted in FIG. 3, according to embodiments, only a portion of the second perovskite layer formed on the donor substrate may be moved on the second perovskite layer.

In step S130, after lamination, heating or pressurization is performed. Then, the donor substrate 130 is separated from the second perovskite layer 140 to form the multilayer perovskite structure 100 according to an embodiment of the present disclosure.

Referring back to FIG. 2, the multilayer perovskite structure 100 manufactured using the method of manufacturing the multilayer perovskite structure 100 according to an embodiment of the present disclosure includes the base substrate 110 and the first and second perovskite layers 120 and 140.

In step S130, in the process of applying heat or pressure when manufacturing the multilayer perovskite structure 100, according to embodiments, only heating may be performed, or both heating and pressurization may be performed.

According to an embodiment, in the method of manufacturing the multilayer perovskite structure 100 according to an embodiment of the present disclosure, a roll-to-roll process may be performed while applying heat or pressure.

In the method of manufacturing the multilayer perovskite structure 100 according to an embodiment of the present disclosure, after the second perovskite layer 140 is brought into contact with the first perovskite layer 120, the compound including the second perovskite precursor may be grown and may be moved onto the first perovskite layer 120.

In this case, due to heat or pressure applied during the process, the compound including the second perovskite precursor may be grown at the interface between the first and second perovskite layers 120 and 140 in the horizontal direction, that is, in a direction parallel to the surface of the first perovskite layer 120.

When the multilayer perovskite structure 100 is manufactured using a method of bringing the second perovskite layer 140 into contact with the first perovskite layer 120, growing the compound including the second perovskite precursor, and moving the grown compound onto the first perovskite layer 120, the multilayer perovskite structure 100 may have excellent reproducibility.

According to an embodiment, by bringing the second perovskite layer 140 into contact with the first perovskite layer 120 and transferring the second perovskite layer 140 to the first perovskite layer 120 by heating or pressurization, the solid-phase multilayer perovskite structure 100 may be manufactured without damage at the contact surface between the first and second perovskite layers 120 and 140.

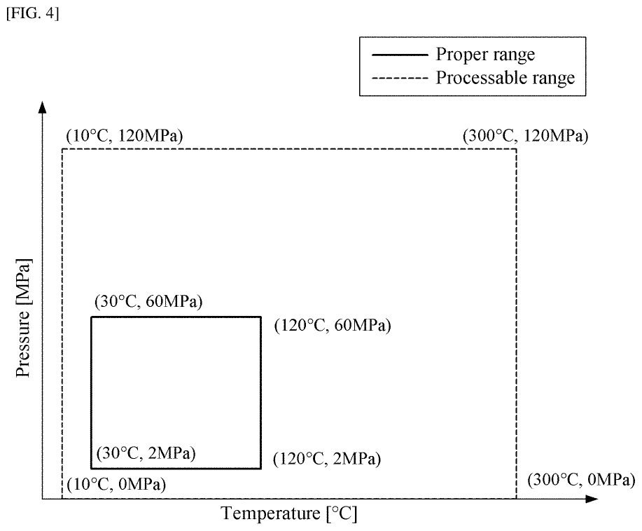

FIG. 4 is a graph showing pressure and temperature conditions for manufacture of a multilayer perovskite structure according to an embodiment of the present disclosure.

Referring to FIG. 4, in step S130, the heating temperature may be, for example, 10° C. to 300° C., preferably 30° C. to 120° C.

When the heating temperature exceed 300° C., thermal decomposition of the compound including the first perovskite precursor and the compound including the second perovskite precursor may occur.

When the heating temperature is less than 10° C., growth of the compound including the second perovskite precursor may be hindered, and thus movement of the second perovskite layer 140 on the first perovskite layer 120 may not be possible.

In step S130, the applied pressure may be, for example, 0 MPa to 120 MPa, preferably 2 MPa to 60 MPa.

When the pressure exceeds 120 MPa, the base substrate 110 on which the first perovskite layer 120 is formed or the donor substrate 130 on which the second perovskite layer 140 is formed may be deformed.

Even when no pressure is applied (0 MPa), movement of the second perovskite layer 140 may proceed. However, in this case, since mechanical adhesion between the first and second perovskite layers 120 and 140 decreases, reproducibility may be degraded.

According to an embodiment, in step S130, after bringing the second perovskite layer 140 into contact with the first perovskite layer 120, the base substrate 110 and the donor substrate 130 may be heated at different temperatures.

For example, after bringing the second perovskite layer 140 into contact with the first perovskite layer 120, the base substrate 110 may be heated at 25° C., and the donor substrate 130 may be heated at 60° C.

In addition, according to an embodiment, in step S130, after bringing the second perovskite layer 140 into contact with the first perovskite layer 120, the base substrate 110 and the donor substrate 130 may be pressurized under different pressures.

According to an embodiment, in step S130, depending on heating time or pressurization time, the growth thickness of the compound including the second perovskite precursor that is grown on the first perovskite layer 120 may be adjusted.

Alternatively, in step S130, depending on heating temperature for the multilayer perovskite structure 100, the growth thickness of the compound including the second perovskite precursor may be adjusted.

According to an embodiment, depending on the type of the compound including the second perovskite precursor, the growth thickness of the second perovskite compound grown on the first perovskite layer 120 may be adjusted.

Specifically, in step S130, heating time or pressurization time may be 1 second to 24 hours.

Accordingly, the growth thickness of the compound including the second perovskite precursor may be 30 nm to 150 nm.

Referring back to FIG. 2, according to the method of manufacturing the multilayer perovskite structure 100 according to an embodiment of the present disclosure, the surface of the first perovskite layer 120 having a three-dimensional structure may be modified with the second perovskite layer 140.

In addition, the multilayer perovskite structure 100 manufactured using the method of manufacturing the multilayer perovskite structure 100 according to an embodiment of the present disclosure may have excellent light conversion efficiency and moisture stability by including both the first perovskite layer 120 having a three-dimensional structure and the second perovskite layer 140 having a zero-, one-, or two-dimensional structure.

In addition, in the multilayer perovskite structure 100 manufactured using the method of manufacturing the multilayer perovskite structure 100 according to an embodiment of the present disclosure, through a simple process of applying heat or pressure, a clear interface between the first and second perovskite layers 120 and 140 having different dimensional structures may be formed without mixing of materials.

According to an embodiment, according to the method of manufacturing the multilayer perovskite structure 100 according to an embodiment of the present disclosure, the second perovskite layer 140 may be brought into contact with a base substrate on which the first perovskite layer 120 is not formed, and then heating or pressurization may be performed to form the multilayer perovskite structure 100.

According to an embodiment, the first perovskite layer may be formed of the compound including the first perovskite precursor having any one of zero-, one-, two-, and three-dimensional structures, and the second perovskite layer may be formed of the compound including the second perovskite precursor having any one of zero-, one-, two-, and three-dimensional structures.

Accordingly, as a result, the second perovskite layer having a two-dimensional structure may be formed on the first perovskite layer having a three-dimensional structure. Also, the second perovskite layer having a three-dimensional structure may be formed on the first perovskite layer having a two-dimensional structure, but the present disclosure is not limited thereto.

FIG. 5 is a perspective view showing a multilayer perovskite structure according to an embodiment of the present disclosure in detail.

Referring to FIG. 5, the multilayer perovskite structure obtained by separating the donor substrate 130 from the second perovskite layer 140 is shown.

That is, the multilayer perovskite structure 100 according to an embodiment of the present disclosure includes the base substrate 110, the first perovskite layer 120 formed on the base substrate 110 and formed of a compound including a first perovskite precursor, and the second perovskite layer 140 formed on the first perovskite layer 120 and formed of a compound including a second perovskite precursor.

In the multilayer perovskite structure 100 according to an embodiment of the present disclosure, an independent interface may be formed while the first perovskite layer 120 and the second perovskite layer 140 are in contact with each other.

Here, the independent interface is an interface formed between the first and second perovskite layers 120 and 140 without mixing of the compound including the first perovskite precursor and the compound including the second perovskite precursor in a state wherein the first and second perovskite layers 120 and 140 are in contact with each other.

In the multilayer perovskite structure 100 according to an embodiment of the present disclosure, the compound including the second perovskite precursor included in the second perovskite layer 140 may be grown on the first perovskite layer 120.

Due to heat or pressure applied during the process, the compound including the second perovskite precursor may be grown at the interface between the first and second perovskite layers 120 and 140 in the horizontal direction, that is, in a direction parallel to the surface of the first perovskite layer 120.

According to an embodiment, the second perovskite layer 140 may be brought into contact with the first perovskite layer 120, and may be transferred to the first perovskite layer 120 by heating or pressurization to manufacture the solid-phase multilayer perovskite structure 100.

The first perovskite layer 120 may be formed of the compound including the first perovskite precursor having a three-dimensional structure.

Accordingly, the first perovskite layer 120 formed of the compound including the first perovskite precursor having a three-dimensional structure may have high light conversion efficiency due to the nature of the crystal structure of the compound including the first perovskite precursor.

Since the method of forming the first perovskite layer 120 and detailed description of the compound including the first perovskite precursor have been described with reference to FIG. 2, repeated description thereof is omitted.

The second perovskite layer 140 may be formed of the compound including the second perovskite precursor having any one of zero-, one-, and two-dimensional structures.

Specifically, the compound including the second perovskite precursor having a one-dimensional structure may have a fiber structure, and the compound including the second perovskite precursor having a two-dimensional structure may have a planar structure.

According to an embodiment, the second perovskite layer 140 may include both the compound including the second perovskite precursor having a one-dimensional structure and the compound including the second perovskite precursor having a two-dimensional structure.

According to an embodiment, the compound including the first perovskite precursor forming the first perovskite layer and the compound including the second perovskite precursor forming the second perovskite layer may have any one of zero-, one-, two-, and three-dimensional structures.

According to an embodiment, the second perovskite layer having a three-dimensional structure may be formed on the first perovskite layer having a one-dimensional structure.

The method of forming the second perovskite layer 140 and detailed description of the compound including the second perovskite precursor have been described with reference to FIG. 2, and thus repeated description thereof is omitted.

In the multilayer perovskite structure 100 according to an embodiment of the present disclosure, when the second perovskite layer 140 is brought into contact with the first perovskite layer 120, the compound including the second perovskite precursor may be grown, and the second perovskite layer 140 may be disposed without separation on the first perovskite layer 120.

In the multilayer perovskite structure 100 according to an embodiment of the present disclosure, depending on heat treatment temperature or heat treatment time during manufacture, the growth thickness of the compound including the second perovskite precursor may be adjusted.

Specifically, in the multilayer perovskite structure 100 according to an embodiment of the present disclosure, the growth thickness of the compound including the second perovskite precursor may be 30 nm to 150 nm.

According to an embodiment, the second perovskite layer 140 may be formed on the base substrate 110 on which the first perovskite layer 120 is not formed.

According to the multilayer perovskite structure 100 according to an embodiment of the present disclosure, by providing the multilayer structure consisting of the three-dimensional perovskite compound having excellent light conversion efficiency and the zero-, one-, or two-dimensional perovskite compound having excellent moisture stability, light conversion efficiency and moisture stability may be achieved at the same time.

In the multilayer perovskite structure 100 according to an embodiment of the present disclosure, when laminating, an independent interface that clearly distinguishes between two perovskite layers formed of different materials is formed. Accordingly, unlike the conventional multilayer perovskite structure 100, the materials may not be mixed.

In addition, the multilayer perovskite structure 100 according to an embodiment of the present disclosure may be a nanometer-scale single film.

Since the multilayer perovskite structure 100 according to an embodiment of the present disclosure is manufactured using the method of manufacturing the multilayer perovskite structure 100 according to an embodiment of the present disclosure, description overlapping with the description described with reference to FIGS. 2 to 4 will be omitted.

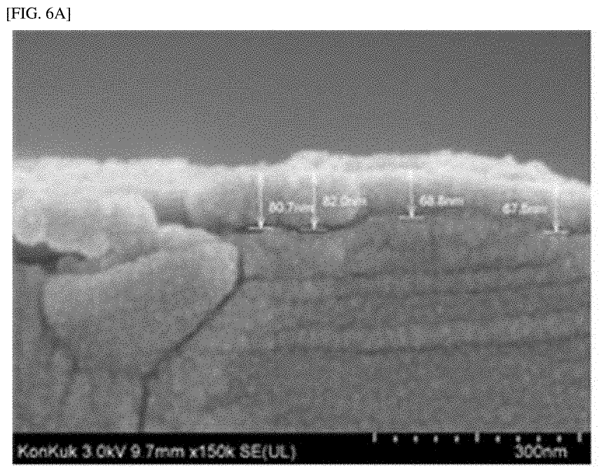

FIG. 6A is a scanning electron microscope (SEM) image showing the cross section of a multilayer perovskite structure according to an embodiment of the present disclosure, and FIG. 6B is a low-magnification scanning electron microscope (SEM) image showing the cross section of a multilayer perovskite structure according to an embodiment of the present disclosure.

Referring to FIGS. 6A and 6B, it can be confirmed that, in the multilayer perovskite structure 100 according to an embodiment of the present disclosure, the first and second perovskite layers 120 and 140 are clearly distinguished, and an independent interface is formed.

In addition, it can be confirmed that the multilayer perovskite structure 100 according to an embodiment of the present disclosure is formed as a nanometer-scale single film.

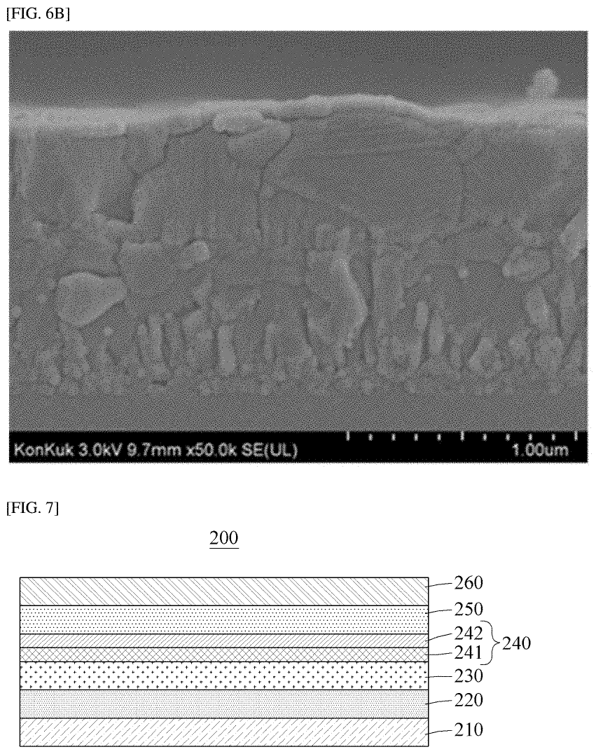

Since the multilayer perovskite structure 100 according to an embodiment of the present disclosure has excellent light conversion efficiency and moisture stability, the multilayer perovskite structure 100 may be applied to a solar cell. This will be described in detail below with reference to FIG. 7.

FIG. 7 is a cross-sectional view showing a solar cell according to an embodiment of the present disclosure in detail.

Referring to FIG. 7, a solar cell 200 according to an embodiment of the present disclosure includes a base substrate 210, a first electrode 220 formed on the base substrate 210, a first charge transport layer 230 formed on the first electrode 220, a perovskite photoactive layer 240 formed on the first charge transport layer 230, a second charge transport layer 250 formed on the perovskite photoactive layer 240, and a second electrode 260 formed on the second charge transport layer 250.

The base substrate 210 is a substrate on which the first electrode 220 is formed, and may be formed of a transparent material through which light is transmitted in consideration of the properties of the solar cell 200.

The base substrate 210 has been described in detail with reference to FIGS. 2 to 4, and thus repeated description thereof is omitted.

For example, the first electrode 220 may be selected from fluorine-doped tin oxide (FTO), indium-doped tin oxide (ITO), aluminum-doped zinc oxide (AZO), indium-doped zinc oxide (IZO), or a mixture thereof, without being limited thereto.

Preferably, the first electrode 220 may include indium-doped tin oxide (ITO), which is a transparent electrode with a high work function, to facilitate injection of holes into the highest occupied molecular orbital (HOMO) level of the perovskite photoactive layer 240.

The first electrode 220 may be formed on a substrate using thermal evaporation, e-beam evaporation, radio frequency (RF) sputtering, magnetron sputtering, vacuum deposition, or chemical vapor deposition.

In addition, the first electrode 220 may include a transparent conductive electrode of an OMO (O: organic or metal oxide, M: metal) structure.

According to an embodiment, the first electrode 220 may have a surface resistance of 1 Ω/cm² to 1,000 Ω/cm² and a transmittance of 80% to 99.9%.

When the surface resistance of the first electrode 220 is less than 1 Ω/cm², transmittance may be degraded, and thus the first electrode 220 may not be used as a transparent electrode. When the surface resistance of the first electrode 220 exceeds 1,000 Ω/cm², device performance may be degraded due to high surface resistance.

In addition, when the transmittance of the first electrode 220 is less than 80%, device performance may be degraded due to deterioration in light extraction or light transmission. When the transmittance of the first electrode 220 exceeds 99.9%, device performance may be degraded due to high surface resistance.

The first charge transport layer 230 may be disposed between the first electrode 220 and the perovskite photoactive layer 240. The first charge transport layer 230 may be an electron transport layer or a hole transport layer. More specifically, when the first charge transport layer 230 is an electron transport layer, the second charge transport layer 250 to be described later may be a hole transport layer. Alternatively, when the first charge transport layer 230 is a hole transport layer, the second charge transport layer 250 to be described later may be an electron transport layer.

In the solar cell 200 according to an embodiment of the present disclosure, when the first charge transport layer 230 is an electron transport layer, the first charge transport layer 230 may easily transfer electrons generated in the perovskite photoactive layer 240 to the first electrode 220.

When the first charge transport layer 230 is an electron transport layer, the first charge transport layer 230 may include at least one of fullerene C60, fullerene derivatives, perylene, 2,2′,2″-(1,3,5-benzinetriyl)-tris(1-phenyl-1-H-benzimidazole) (TPBi), polybenzimidazole (PBI), 3,4,9,10-perylene-tetracarboxylic bis-benzimidazole (PTCBI), naphthalene diimide (NDI) and derivatives thereof, TiO₂, SnO₂, ZnO, ZnSnO₃, 2,4,6-tris(3-(pyrimidin-5-yl)phenyl)-1,3,5-triazine, 8-hydroxyquinolinolato-lithium, 1,3,5-tris (1-phenyl-1Hbenzimidazol-2-yl)benzene, 6,6′-bis[5-(biphenyl-4-yl)-1,3,4-oxadiazo-2-yl]-2,2′-bipyridyl, 4,4′-bis(4,6-diphenyl-1,3,5-triazin-2-yl)biphenyl (BTB), rubidium carbonate (Rb₂CO₃), and rhenium (VI) oxide (ReO₃). The fullerene derivative may be (6,6)-phenyl-C61-butyric acid-methyl ester (PCBM) or (6,6)-phenyl-C61-butyric acid cholesteryl ester (PCBCR), without being limited thereto.

In an inverted structure, TiO₂-based or Al₂O₃-based porous materials may be mainly used as the first charge transport layer 230 of an electron transport layer, without being limited thereto.

The first charge transport layer 230 may be formed by applying the exemplified material using spray coating, spin coating, ultra-spray coating, electrospinning coating, slot die coating, gravure coating, bar coating, roll coating, dip coating, shear coating, screen printing, inkjet printing, or nozzle printing, without being limited thereto.

The perovskite photoactive layer 240 may be formed between the first and second charge transport layers 230 and 250.

The perovskite photoactive layer 240 may include a first perovskite layer 241 formed of a compound including a first perovskite precursor and a second perovskite layer 242 formed of a compound including a second perovskite precursor.

The first and second perovskite layers 241 and 242 have the same properties as the first and second perovskite layers of the multilayer perovskite structure according to an embodiment of the present disclosure, and thus repeated description thereof is omitted.

The first perovskite layer 241 may be formed on the first charge transport layer 230.

The first perovskite layer 241 may be formed on the first charge transport layer 230 by applying a solution including the compound including the first perovskite precursor onto the first charge transport layer 230.

Specifically, the first perovskite layer 241 may be formed by applying the solution including the compound including the first perovskite precursor using spray coating, spin coating, ultra-spray coating, electrospinning coating, slot die coating, gravure coating, bar coating, roll coating, dip coating, shear coating, screen printing, inkjet printing, or nozzle printing, without being limited thereto.

According to an embodiment, before the first perovskite layer 241 is formed, the first charge transport layer 230 formed on the base substrate 210 may be pre-heated, and then the solution including the compound including the first perovskite precursor may be applied.

The first perovskite precursor included in the first perovskite layer 241 may be represented by Chemical Formula 1. The first perovskite precursor has been described with reference to FIG. 2, and thus repeated description thereof is omitted.

The compound including the first perovskite precursor may have a three-dimensional structure. Due to these structural properties, the compound may have excellent light conversion efficiency.

The second perovskite layer 242 may be formed on a donor substrate (not shown) in advance, and then may be transferred to the first perovskite layer 241 so that the second perovskite layer 242 is formed on the first perovskite layer 241.

That is, as a result, the second perovskite layer 242 may be formed between the first perovskite layer 241 and the second charge transport layer 250.

The second perovskite layer 242 may be formed on the donor substrate by applying a solution including the compound including the second perovskite precursor onto the donor substrate.

The donor substrate has been described with reference to FIG. 2, and thus repeated description thereof is omitted.

The second perovskite layer 242 may be formed by applying the solution including the compound including the second perovskite precursor using spray coating, spin coating, ultra-spray coating, electrospinning coating, slot die coating, gravure coating, bar coating, roll coating, dip coating, shear coating, screen printing, inkjet printing, or nozzle printing, without being limited thereto.

The second perovskite precursor included in the second perovskite layer 242 may be represented by Chemical Formula 2. The second perovskite precursor has been described with reference to FIG. 2, and thus repeated description thereof is omitted.

The compound including the second perovskite precursor may have a zero-dimensional structure, a one-dimensional fiber structure, or a two-dimensional planar structure. Due to these structural properties, the compound may have excellent moisture stability.

The second perovskite layer 242 formed on the donor substrate may be disposed to contact the first perovskite layer 241, and the second perovskite layer 242 may be transferred onto the first perovskite layer 241 by applying heat or pressure.

In this case, an independent interface is formed between the first and second perovskite layers 241 and 242 in contact with each other so that the first and second perovskite layers 241 and 242 are clearly distinguished.

Specifically, after the second perovskite layer 242 is disposed on the first perovskite layer 241, the compound including the second perovskite precursor may be grown by heating or pressurization so that the second perovskite layer 242 may be transferred onto the first perovskite layer 241 while forming an independent interface.

The compound including the second perovskite precursor may be grown, on the first perovskite layer 241, in a direction parallel to the surface of the first perovskite layer 241.

According to an embodiment, depending on heat treatment temperature or heat treatment time, the thickness of the compound including the second perovskite precursor grown on the first perovskite layer 241 may be adjusted.

Specifically, the compound including the second perovskite precursor may be grown to a thickness of 30 nm to 150 nm on the first perovskite layer 241.

According to an embodiment, the second perovskite layer 242 may be transferred onto the first perovskite layer 241 by heating or pressurization while forming an independent interface.

The independent interface formed between the first and second perovskite layers 241 and 242 has been described with reference to FIG. 5, and thus repeated description thereof is omitted.

The first perovskite layer 241 may be formed of the compound including the first perovskite precursor having a three-dimensional structure, and the second perovskite layer 242 may be formed of the compound including the second perovskite precursor having any one of a zero-dimensional structure, a one-dimensional fiber structure, and a two-dimensional planar structure.

Accordingly, since the solar cell 200 according to an embodiment of the present disclosure includes the perovskite photoactive layer 240 including the first perovskite layer 241 having excellent light conversion efficiency and the second perovskite layer 242 having excellent moisture stability, the solar cell 200 may have excellent light conversion efficiency and moisture stability at the same time.

The second charge transport layer 250 may be an electron transport layer or a hole transport layer. More specifically, when the above-described first charge transport layer 230 is an electron transport layer, the second charge transport layer 250 may be a hole transport layer. Alternatively, when the above-described first charge transport layer 230 is a hole transport layer, the second charge transport layer 250 may be an electron transport layer.

According to an embodiment of the present disclosure, when the second charge transport layer 250 is a hole transport layer, in the solar cell 200 according to an embodiment of the present disclosure, the second charge transport layer 250 may easily transfer holes generated in the perovskite photoactive layer 240 to the second electrode 260.

When the second charge transport layer 250 is a hole transport layer, the second charge transport layer 250 may include at least one of poly(3-hexylthiophene) (P3HT), poly[2-methoxy-5-(3′,7′-dimethyloctyloxyl)]-1,4-phenylene vinylene (MDMO-PPV), poly[2-methoxy-5-(2″-ethylhexyloxy)-p-phenylene vinylene] (MEH-PPV), poly(3-octyl thiophene) (P3OT), poly(octyl thiophene) (POT), poly(3-decyl thiophene) (P3DT), poly(3-dodecyl thiophene) (P3DDT), poly(p-phenylene vinylene) (PPV), poly(9,9′-dioctylfluorene-co-N-(4-butylphenyl)diphenyl amine) (TF3), polyaniline, 2,22′,7,77′-tetrkis(N,N-dipmethoxyphenylamine)-9,9,9′-spirobi fluorine (spiro-OMeTAD), CuSCN, CuI, MoON, VON, NiON, CuON, poly[2,1,3-benzothiadiazole-4,7-diyl[4,4-bis(2-ethylhexyl-4H-cyclopenta[2,1-b:3,4-b′]dithiophene-2,6-diyl]] (PCPDTBT), poly[(4,4′-bis(2-ethylhexyl)dithieno[3,2-b:2′,3′-d]silole)-2,6-diyl-alt-(2,1,3-benzothiadiazole)-4,7-diyl] (Si-PCPDTBT), poly((4,8-diethylhexyloxyl) benzo([1,2-b:4,5-b]dithiophene)-2,6-diyl)-alt-((5-octylthieno[3,4-c]pyrrole-4,6-dione)-1,3-diyl) (PBDTTPD), poly[2,7-(9-(2-ethylhexyl)-9-hexyl-fluorene)-alt-5,5-(4′,7,-di-2-thienyl-2′,1′,3′-benzothiadiazole)] (PFDTBT), poly[2,7-0.9,9-(dioctyl-fluorene)-alt-5,5-(4′,7′-di-2-.thienyl-2′, 1′, 3′-benzothiadiazole)] (PFO-DBT), poly[(2,7-dioctylsilafluorene)-2,7-diyl-alt-(4,7-bis(2-thienyl)-2,1,3-benzothiadiazole)-5,5′-diyl] (PSiFDTBT), poly[(4,4′-bis(2-ethylhexyl)dithieno[3,2-b: 2′,3′-d]silole)-2,6-diyl-alt-(2,1,3-benzothiadiazole)-4,7-diyl] (PSBTBT), poly[[9-(1-octylnonyl)-9H-carbazole-2,7-diyl]-2,5-thiophenediyl-2,1,3-benzothiadiazole-4,7-diyl-2,5-thiophenediyl] (PCDTBT), poly(9,9′-dioctylfluorene-co-bis(N,N′-(4,butylphenyl))bis(N,N′-phenyl-1,4-phenylene)diamine) (PFB), poly(9,9′-dioctylfluorene-cobenzothiadiazole) (F8BT), poly(3,4-ethylenedioxythiophene) (PEDOT), PEDOT:PSS, poly(3,4-ethylenedioxythiophene)-poly(styrenesulfonate), poly(triarylamine) (PTAA), poly(4-butylphenyldiphenyl-amine), 4,4′-bis[N-(1-naphtyl)-N-phenylamino]-biphenyl (NPD), PEDOT: PSS/bis(N-(1-naphthyl-n-phenyl))benzidine(α-NPD) mixed with perfluorinated ionomer (PFI), N,N′-di(naphthalene-1-yl)-N,N′-diphenyl-benzidine (NPB), N,N′-diphenyl-N,N′-bis(3-methylphenyl)-1,1′-diphenyl-4,4′-diamine (TPD), copper phthalocyanine (CuPc), 4,4′,4″-tris (3-methylphenylamino)triphenylamine (m-MTDATA), 4,4′,4″-tris(3-methylphenylamino)henoxybenzene (m-MTDAPB), 4,4′,4″-tri(N-carbazolyl)triphenylamine (TCTA) that is a starburst amine, 4,4′,4″-tris(N-(2-naphthyl)-N-phenylamino)-triphenylamine (2-TNATA), and copolymers thereof, without being limited thereto.

The second charge transport layer 250 may be formed by applying the exemplified material using spray coating, spin coating, ultra-spray coating, electrospinning coating, slot die coating, gravure coating, bar coating, roll coating, dip coating, shear coating, screen printing, inkjet printing, or nozzle printing, without being limited thereto.

The second electrode 260 may be any commonly used back electrode. Specifically, the second electrode 260 may be lithium fluoride/aluminum (LiF/Al), gold (Au), silver (Ag), platinum (Pt), palladium (Pd), copper (Cu), aluminum (Al), carbon (C), cobalt sulfide (CoS), copper sulfide (CuS), nickel oxide (NiO), or a mixture thereof, without being limited thereto.

The second electrode 260 may also be formed using the method used to form the first electrode 220, and thus repeated description thereof is omitted.

To facilitate injection of electrons into the highest occupied molecular orbital (HOMO) level of the perovskite photoactive layer 240, metal electrodes having low work function and excellent internal reflectance may be used as the second electrode 260.

Referring to FIG. 7, in the solar cell 200 according to an embodiment of the present disclosure, the second perovskite layer 242 is disposed on the first perovskite layer 241 included in the perovskite photoactive layer 240.

According to an embodiment, although not shown in the drawing, depending on the method of forming the second perovskite layer 242 and the method of moving the second perovskite layer 242 described above, the second perovskite layer 242 may be disposed above the first electrode 220, the first charge transport layer 230, the second charge transport layer 250, and the second electrode 260.

Accordingly, the perovskite photoactive layer 240 may include only the first perovskite layer 241, and the second perovskite layer 242 may be disposed on any one of the first electrode 220, the first charge transport layer 230, the second charge transport layer 250, and the second electrode 260.

Depending on the above-described method of manufacturing the multilayer perovskite structure, in the solar cell 200 according to an embodiment of the present disclosure, the second perovskite layer 242 formed of the compound including the second perovskite precursor may be stably transferred, and the second perovskite layer 242 may be freely positioned in the configuration of the solar cell 200. Thereby, the surface of each component may be modified.

After manufacturing the multilayer perovskite structure and the solar cell according to the present disclosure, the properties and effects thereof were evaluated through various embodiments. The results are described below.

### Example 1

A [CH₃NH₃PbBr₃]_{0.05}[HC(NH₂)₂PbI₃]_{0.95} solution having a concentration of 1 M was prepared by dissolving CH₃NH₃Br₂ and PbBr₂ in a molar ratio of 1:1, HC(NH₂)₂I and PbI₂ in a molar ratio of 1:1, and CH₃NH₃Br₂ and HC(NH₂)₂I in a molar ratio of 1:4 in a solvent containing dimethylsulfoxide and dimethylformamide in a ratio of 1:8.

A glass substrate coated with fluorine-doped tin oxide having a size of 1×1 inch (FTO; F-doped SnO₂, 8 ohms/cm², Pilkington, hereinafter referred to as FTO substrate) was washed with distilled water containing a surfactant and with ethanol sequentially.

The prepared solution was applied onto the washed FTO substrate. At this time, the solution was applied in batch to the center of rotation of the FTO substrate. Then, spin coating was performed at 5,000 rpm.

When spin coating time reached 25 seconds, a non-solvent diethyl ether was applied in batch to the center of rotation of the spinning FTO substrate, and then spin coating was additionally performed for 5 seconds.

After performing spin coating, the substrate was placed on a hot plate at 150° C. under atmospheric pressure for 10 minutes to form a first perovskite layer formed of a halide ([CH₃NH₃PbBr₃]_{0.2}[HC(NH₂)₂PbI₃]_{0.8}) of a three-dimensional structure.

A solution was prepared by dissolving, at a concentration of 0.8 M, a second perovskite precursor (CH₃(CH₂)₃NH₃)₂PbI₄ having a two-dimensional structure in a solvent containing dimethylformamide and dimethylsulfoxide in a ratio of 4:1, and spin coating was performed on an ITO substrate at 6,000 rpm using 45 μl of the solution.

Thereafter, heating was performed at 100° C. for 20 minutes to form a second perovskite layer.

After placing the first and second perovskite layers to be contact with each other, heating and pressurization were performed for 10 minutes. Specifically, the substrate on which the first perovskite layer was formed was heated at 25° C., the substrate on which the second perovskite layer was formed was heated at 30° C., and a pressure of 60 MPa was applied to both substrates.

Thereafter, the substrate on which the second perovskite layer was formed was separated from the second perovskite layer to form a multilayer perovskite structure in which perovskite layers of three- and two-dimensional structures were formed.

### Example 2

A multilayer perovskite structure was manufactured in the same manner as in Example 1, except that the substrate on which the second perovskite layer was formed was heat-treated at 60° C.

### Example 3

A multilayer perovskite structure was manufactured in the same manner as in Example 1, except that the substrate on which the second perovskite layer was formed was heat-treated at 70° C.

### Example 4

A multilayer perovskite structure was manufactured in the same manner as in Example 1, except that the substrate on which the second perovskite layer was formed was heat-treated at 90° C.

### Example 5

A multilayer perovskite structure was manufactured in the same manner as in Example 1, except that the substrate on which the second perovskite layer was formed was heat-treated at 100° C.

### Example 6

A multilayer perovskite structure was manufactured in the same manner as in Example 1, except that the substrate on which the second perovskite layer was formed was heat-treated at 120° C.

### Comparative Example 1

A multilayer perovskite structure was manufactured in the same manner as in Example 1, except that only the first perovskite layer was formed on the FTO substrate.

### Comparative Example 2

A multilayer perovskite structure was manufactured in the same manner as in Example 1, except that the first perovskite layer was formed on the FTO substrate, the first perovskite layer was covered with the washed quartz glass substrate, and then only pressure was applied.

### Example 7

A patterned FTO glass substrate (25 mm×25 mm ITO substrate, etching area: 10 mm×25 mm) was washed sequentially with a cleaning solution, deionized water, acetone, and ethanol and was dried using compressed N₂ gas.

The washed FTO glass substrate was treated with argon (Ar) plasma for 1 minutes to remove organic residues and make the surface thereof hydrophilic.

The FTO glass substrate having a hydrophilized surface was coated with TiO₂ through spin coating, and then annealing was performed to form an electron transport layer.

The perovskite photoactive layer (first perovskite layer (3D)/second perovskite layer (2D)) was formed on the electron transport layer using the same manner as Example 1.

Thereafter, a P3HT solution having a concentration of 10 g/L (prepared by dissolving P3HT according to the concentration of chlorobenzene) was applied in batch to the center of rotation of the perovskite photoactive layer, followed by spin coating at 3,000 rpm for 30 seconds to form a hole transport layer.

The formed hole transport layer of the multilayer perovskite structure was masked, and then a gold (Au) electrode having a thickness of 130 nm was deposited on the hole transport layer using a vacuum evaporator (maintaining a vacuum of 5×10⁻⁶ torr) to form a second electrode. Through this process, a solar cell (FTO/TIO₂/first perovskite layer (3D)/second perovskite layer (2D)/P3HT/Au) was manufactured.

### Comparative Example 3

A solar cell (FTO/TIO₂/first perovskite layer (3D)/P3HT/Au) was manufactured in the same manner as in Example 7, except that the perovskite photoactive layer included only the first perovskite layer.

### Example 8

A solar cell (FTO/TIO₂/first perovskite layer (3D)/second perovskite layer (2D)/Sprio-OMeTAD/Au) was manufactured in the same manner as in Example 7, except for the following procedures: A Spiro-OMeTAD solution, as a first solution, was prepared by dissolving Spiro-OMeTAD at a concentration of 0.1 g/1.1 mL in a chlorobenzene (CB) solvent, a lithium salt (Li-salt) solution, as a second solution, was prepared by dissolving lithium salt at a concentration of 0.54 g/mL in an acetonitrile (ACN) solvent, and a tris(2-(1H-pyrazol-1-yl)-4-tert-butylpyridine)-cobalt(III)tris(bis(trifluoromethylsulfonyl)imide) (FK209) solution, as a third solution, was prepared by dissolving KF209 at a concentration of 0.375 g/mL in an acetonitrile (ACN) solvent. Then, 23 μl of the second solution, 10 μl of the third solution, and 39 μl of 4-tert-butyl pyridine (TBP) were added to the first solution to prepared a mixed solution, and then spin coating was performed at 2,000 rpm for 34 seconds using the prepared mixed solution to form a hole transport layer.

### Comparative Example 4

A solar cell (FTO/TIO₂/first perovskite layer (3D)/Sprio-OMeTAD/Au) was manufactured in the same manner as in Comparative Example 3, except for the following procedures: A Spiro-OMeTAD solution, as the first solution, was prepared by dissolving Spiro-OMeTAD at a concentration of 0.1 g/1.1 mL in a chlorobenzene (CB) solvent, a lithium salt (Li-salt) solution, as the second solution, was prepared by dissolving lithium salt at a concentration of 0.54 g/mL in an acetonitrile (ACN) solvent, and a tris(2-(1H-pyrazol-1-yl)-4-tert-butylpyridine)-cobalt(III) tris(bis(trifluoromethylsulfonyl)imide) (FK209) solution, as the third solution, was prepared by dissolving FK209 at a concentration of 0.375 g/mL in an acetonitrile (ACN) solvent. Then, 23 μl of the second solution, 10 μl of the third solution, and 39 μl of 4-tert-butyl pyridine (TBP) were added to the first solution to prepare a mixed solution, and spin coating was performed at 2,000 rpm for 34 seconds using the prepared mixed solution to form the hole transport layer.

### Example 9

A solar cell (FTO/SnO₂/first perovskite layer (3D)/second perovskite layer (2D)/PTAA/Au) was manufactured in the same manner as in Example 7, except for the following procedures: SnO₂ was deposited on the FTO glass substrate having a hydrophilized surface through a chemical bath deposition (CBD) process, and then annealing was performed to form an electron transport layer. 6 μl of a lithium salt (Li-salt) storage solution (stock solution) and 6 μl of 4-tert-butyl pyridine (TBP) were added to a poly(triarylamine) (PTAA) solution (in toluene) having a concentration of 12 mg/mL to prepare a mixed solution, and then spin coating was performed at 3,000 rpm for 34 seconds using the prepared mixed solution to form a hole transport layer.

### Comparative Example 5

A solar cell (FTO/SnO₂/first perovskite layer (3D)/PTAA/Au) was manufactured in the same manner as in Comparative Example 3, except for the following procedures: SnO₂ was deposited on the FTO glass substrate having a hydrophilized surface through a chemical bath deposition (CBD) process, and then annealing was performed to form an electron transport layer. 6 μl of a lithium salt (Li-salt) storage solution (stock solution) and 6 μl of 4-tert-butyl pyridine (TBP) were added to a poly(triarylamine) (PTAA) solution (in toluene) having a concentration of 12 mg/mL to prepare a mixed solution, and then spin coating was performed at 3,000 rpm for 34 seconds using the prepared mixed solution to form a hole transport layer.

### Example 10

A solar cell (FTO/SnO₂/first perovskite layer (3D)/second perovskite layer (2D)/P3HT/Au) was manufactured in the same manner as in Example 7, except that SnO₂ was deposited on the FTO glass substrate having a hydrophilized surface through a chemical bath deposition (CBD) process, and then annealing was performed to form an electron transport layer.

### Comparative Example 6

A solar cell (FTO/SnO₂/first perovskite layer (3D)/P3HT/Au) was manufactured in the same manner as in Comparative Example 3, except that SnO₂ was deposited on the FTO glass substrate having a hydrophilized surface through a chemical bath deposition (CBD) process, and then annealing was performed to form an electron transport layer.

### Example 11

A solar cell (FTO/SnO₂/first perovskite layer (3D)/second perovskite layer (2D)/Spiro-OMeTAD/Au) was manufactured in the same manner as in Example 7, except for the following procedures: SnO₂ was deposited on the FTO glass substrate having a hydrophilized surface through a chemical bath deposition (CBD) process, and then annealing was performed to form an electron transport layer. A Spiro-OMeTAD solution, as the first solution, was prepared by dissolving Spiro-OMeTAD at a concentration of 0.1 g/1.1 mL in a chlorobenzene (CB) solvent, a lithium salt (Li-salt) solution, as the second solution, was prepared by dissolving lithium salt at a concentration of 0.54 g/mL in an acetonitrile (ACN) solvent, and a tris(2-(1H-pyrazol-1-yl)-4-tert-butylpyridine)-cobalt(III) tris(bis(trifluoromethylsulfonyl)imide) (FK209) solution, as the third solution, was prepared by dissolving FK209 at a concentration of 0.375 g/mL in an acetonitrile (ACN) solvent. Then, 23 μl of the second solution, 10 μl of the third solution, and 39 μl of 4-tert-butyl pyridine (TBP) were added to the first solution to prepare a mixed solution, and spin coating was performed at 2,000 rpm for 34 seconds using the prepared mixed solution to form the hole transport layer.

### Comparative Example 7

A solar cell (FTO/SnO₂/first perovskite layer (3D)/Spiro-OMeTAD/Au) was manufactured in the same manner as in Comparative Example 3, except for the following procedures: SnO₂ was deposited on the FTO glass substrate having a hydrophilized surface through a chemical bath deposition (CBD) process, and then annealing was performed to form an electron transport layer. A Spiro-OMeTAD solution, as the first solution, was prepared by dissolving Spiro-OMeTAD at a concentration of 0.1 g/1.1 mL in a chlorobenzene (CB) solvent, a lithium salt (Li-salt) solution, as the second solution, was prepared by dissolving lithium salt at a concentration of 0.54 g/mL in an acetonitrile (ACN) solvent, and a tris(2-(1H-pyrazol-1-yl)-4-tert-butylpyridine)-cobalt(III) tris(bis(trifluoromethylsulfonyl)imide) (FK209) solution, as the third solution, was prepared by dissolving FK209 at a concentration of 0.375 g/mL in an acetonitrile (ACN) solvent. Then, 23 μl of the second solution, 10 μl of the third solution, and 39 μl of 4-tert-butyl pyridine (TBP) were added to the first solution to prepare a mixed solution, and spin coating was performed at 2,000 rpm for 34 seconds using the prepared mixed solution to form the hole transport layer.

Properties Evaluation

I. Evaluation of Properties of Multilayer Perovskite Structure

1. SEM Observation

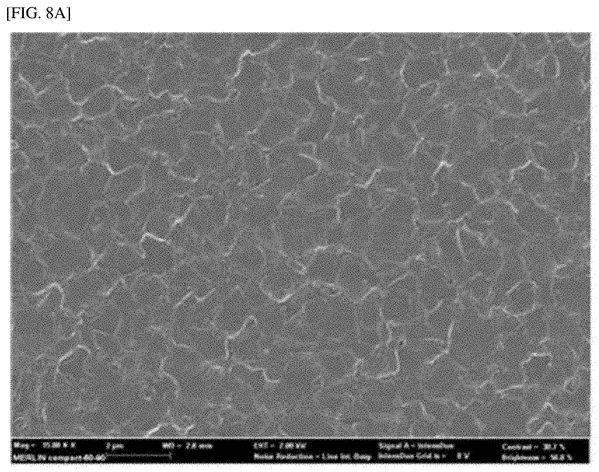

FIG. 8A is a scanning electron microscope (SEM) image showing the surface of a first perovskite layer included in a multilayer perovskite structure according to an embodiment of the present disclosure, and FIG. 8B is an SEM image showing the surface of a second perovskite layer grown on a multilayer perovskite structure according to an embodiment of the present disclosure.

Referring to FIGS. 8A and 8B, it can be confirmed that, for Example 1, the second perovskite layer having a two-dimensional planar structure is formed on the first perovskite layer having a three-dimensional structure.

In addition, it can be confirmed that, depending on heat treatment time or pressurization time, the microscopic second perovskite layer may be evenly transferred.

2. XRD Analysis

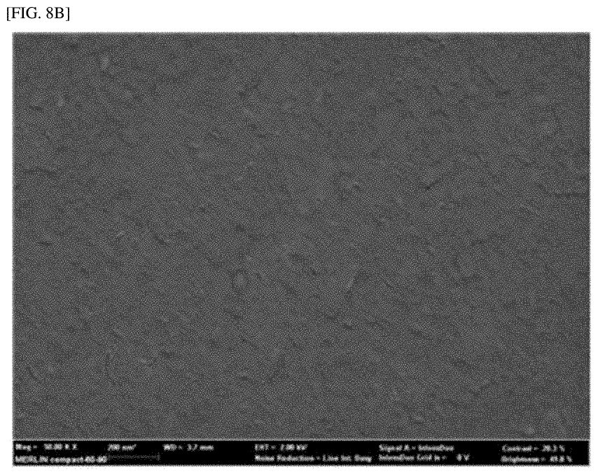

FIG. 9 includes graphs showing x-ray diffraction (XRD) data depending on processing conditions for a multilayer perovskite structure according to an embodiment of the present disclosure.

Referring to the bottom graph of FIG. 9, BA₂PbI₄ and BA₂MAPbI₇ refer to perovskite compounds included in the second perovskite layer having a two-dimensional structure, and the XRD peaks thereof are shown.

Referring to the top graph of FIG. 9, it can be confirmed that the XRD peaks of the perovskite compound included in the second perovskite layer are detected in the XRD peaks of Examples 1 to 4 and reference data (Ref).

In particular, the XRD peaks of the second perovskite layer are observed in the XRD peaks of Examples 1 to 6, indicating that the second perovskite layer is formed in the multilayer perovskite structure.

It can be confirmed that, at heat treatment temperature higher than that of Example 2, peaks corresponding to N=2 are generated by combination of the first and second perovskite layers.

3. Evaluation of Stability of Multilayer Perovskite Structure

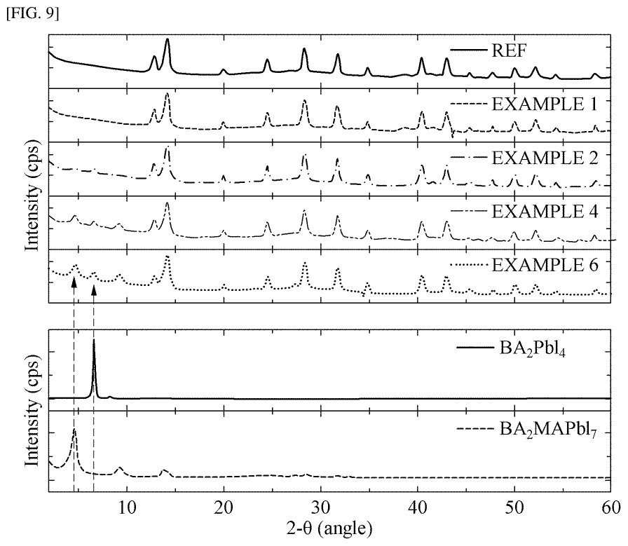

FIG. 10 is an image showing color change over time when a multilayer perovskite structure according to an embodiment of the present disclosure is exposed to humidity.

Referring to FIG. 10, multilayer perovskite structures corresponding to Comparative Example 1, Comparative Example 2, Example 2, and Example 5 were placed in a dial order, and were exposed to a 25% humidity environment at 25° C. and then exposed to a 78% humidity environment. Then, appearance was observed over time. The observed appearance is shown in FIG. 10.

Referring to FIG. 10, visual change is not significant in a 25% humidity environment (low humidity condition) at 25° C. However, 40, 53, and 66 hours after exposure to a 78% humidity environment (high humidity condition) at 25° C., visual change is observed. It can be confirmed that heat treatment temperature is proportional to moisture stability.

II. Evaluation of Properties of Solar Cell

1. SEM Observation

Referring back to FIG. 7, it can be confirmed that crystals constituting the second perovskite layer having a two-dimensional structure are evenly transferred onto the first perovskite layer.

In addition, it can be confirmed that the first and second perovskite layers are clearly distinguished and an independent interface is formed therebetween.

2. Electrical Properties

Eight solar cells were manufactured according to Examples 8 to 11 and Comparative Examples 4 to 7, respectively. Efficiency of each solar cell was measured according to the standard test conditions of a sunshine intensity of 1,000 W/m² and a constant temperature of 25° C., and the average efficiency is summarized in Table 1 below.

Referring to Table 1, it can be confirmed that, in the case of Examples 8 to 11, due to increase in a fill factor (FF) and open-circuit voltage (V_{oc}), power conversion efficiency (PCE)(η) increases.

TABLE 1

| | Electron | Hole | | | | |
|---|---|---|---|---|---|---|
| | transport | transport | J_{sc} | V_{oc} | FF | PCE(η) |
| | layer | layer | [mA/cm²] | [V] | [%] | [%] |
| Example 8 | TiO₂ | Spiro- | 24.5 | 1.18 | 81 | 23.4 |
| Comparative | | OMeTAD | 24.5 | 1.09 | 81 | 21.6 |
| example 4 | | | | | | |
| Example 9 | SnO₂ | PTAA | 24.61 | 1.105 | 81.90 | 22.27 |
| Comparative | | | 24.52 | 1.065 | 81.78 | 21.36 |
| Example 5 | | | | | | |
| Example 10 | SnO₂ | P3HT | 24.175 | 1.12 | 75.79 | 20.52 |
| Comparative | | | 24.00 | 0.37 | 51.11 | 11.92 |
| Example 6 | | | | | | |
| Example 11 | SnO₂ | Spiro- | 24.69 | 1.165 | 83.95 | 24.59 |
| Comparative | | OMeTAD | 24.60 | 1.095 | 82.95 | 22.39 |
| Example 7 | | | | | | |

When comparing Comparative Examples 4 to 7, in which open-circuit voltage is not high, and Examples 8 to 11 manufactured through a process of forming a second perovskite layer by applying heat or pressure, it can be confirmed that, in Examples 8 to 11, power conversion efficiency is greatly improved and hysteresis decreases.

Accordingly, it can be confirmed that the solar cells according to Examples 8 to 11 have excellent power conversion efficiency by including perovskite layers having different dimensional structures.

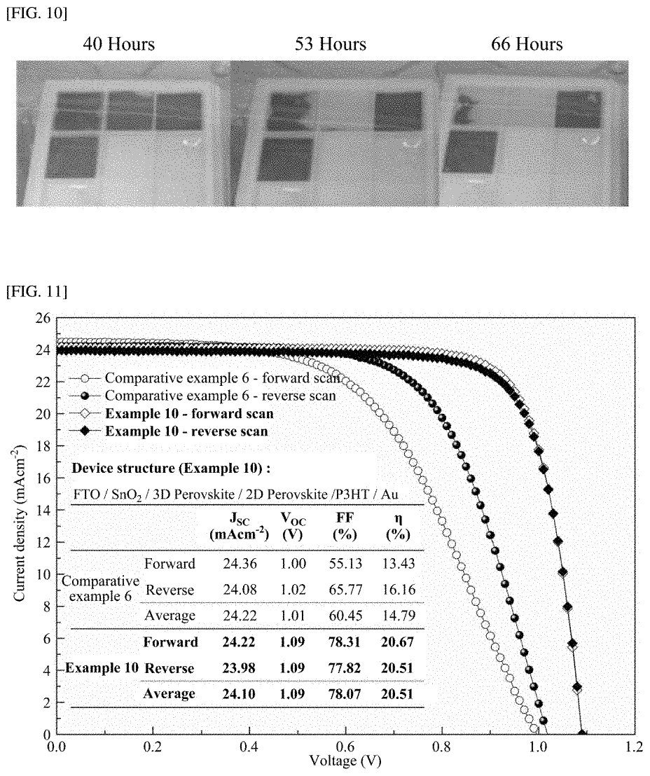

To determine whether the efficiency of the solar cells according to Example 10 and Comparative Example 6 was improved, current-voltage curves were analyzed, and the results are shown in FIG. 11. Referring to FIG. 11, it can be confirmed that the efficiency of the solar cell according to Example 10 is improved.

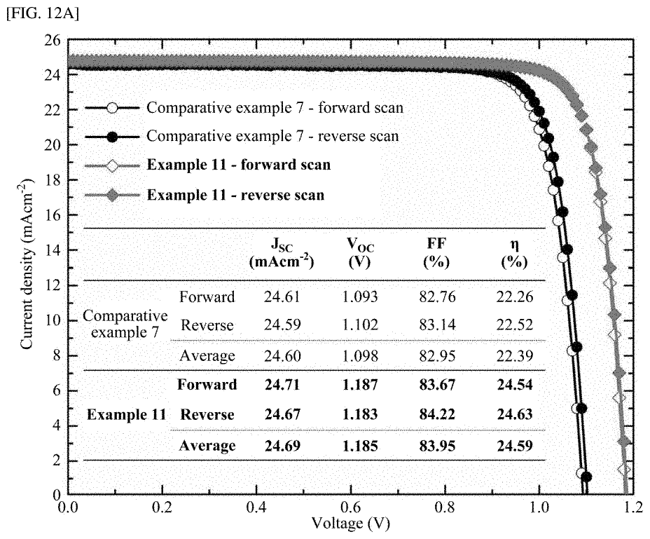

To determine whether the efficiency of the solar cells according to Example 11 and Comparative Example 7 was improved, current-voltage curves were analyzed, and the results are shown in FIG. 12A. Referring to FIG. 12A, it can be confirmed that the efficiency of the solar cell according to Example 11 is improved.

In addition, it was certified by an accredited certification body (Newport Co.) that the solar cell according to Example 11 had a power conversion efficiency of 24.35%, and the certificate is shown in FIG. 12B.

3. Moisture Stability

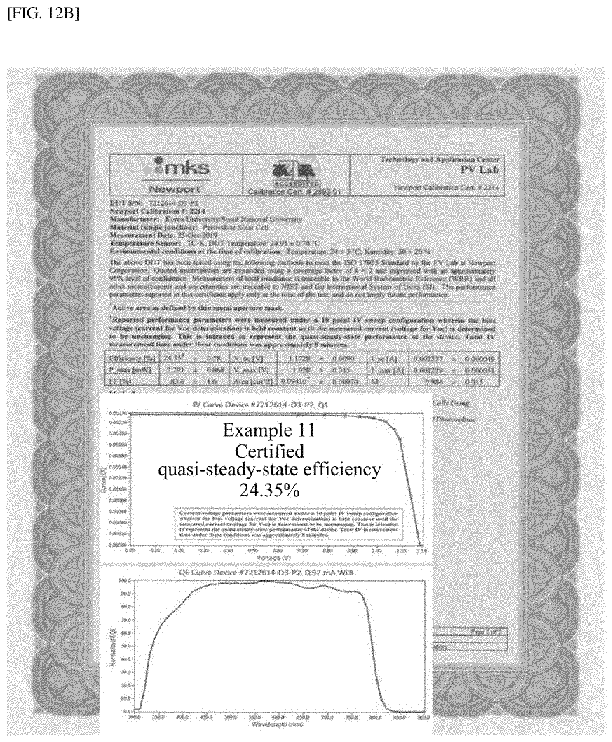

FIG. 13 is a graph showing the long-term efficiency of a multilayer perovskite solar cell according to an embodiment of the present disclosure.

PCE was measured when the conventional solar cell was exposed to a moisture of 25% at 25° C., and the results are shown in FIG. 13.

Referring to FIG. 13, it can be confirmed that the PCE of the conventional solar cell does not change significantly over time, showing PCE of 20% to 25%.

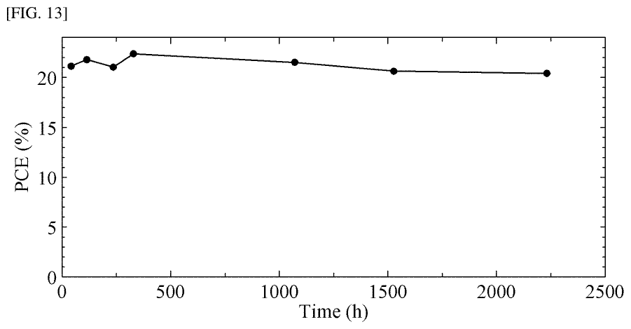

FIG. 14 is a graph showing solar cell efficiency depending on the moisture stability of a solar cell according to an embodiment of the present disclosure.

PCE was measured when the solar cells according to Example 7 and Comparative Example 3 were exposed to a moisture of 85% at 25° C., and the results are shown in FIG. 14.

Referring to FIG. 14, unlike the solar cell of Comparative Example 3 including a single-layer perovskite photoactive layer, the solar cell of Example 7 including the first and second perovskite layers, wherein an independent interface is formed between the first and second perovskite layers, has excellent moisture stability.

In addition, when comparing FIG. 13 and FIG. 14, in the case of the solar cell of Example 7, PCE remains almost the same even in an 85% humidity environment (high humidity condition) at 25° C., indicating that the solar cell of Example 7 has excellent moisture stability.

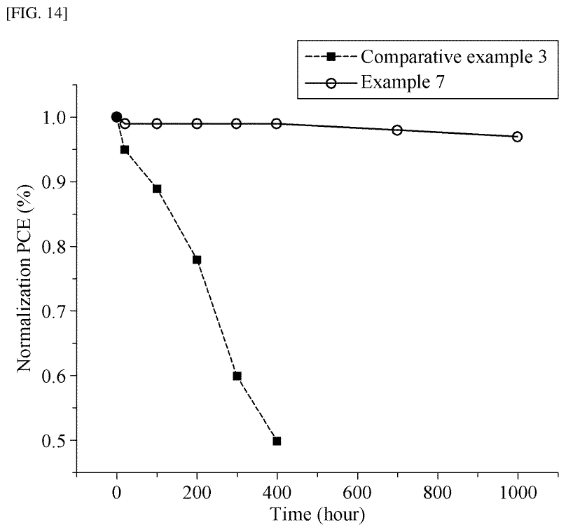

FIG. 15 is a graph showing the solar cell efficiency depending on the moisture stability of the solar cells according to Example 10 and Comparative Example 6.

Referring to FIG. 15, under the conditions of room temperature, 85% relative humidity, and an unencapsulated device, in the case of the solar cell (Control) according to Comparative Example 6, after 400 hours, efficiency decrease 41.1%. In the case of the solar cell (SIG60) according to Example 10, even after 1,000 hours, efficiency decreases only 2.5%.

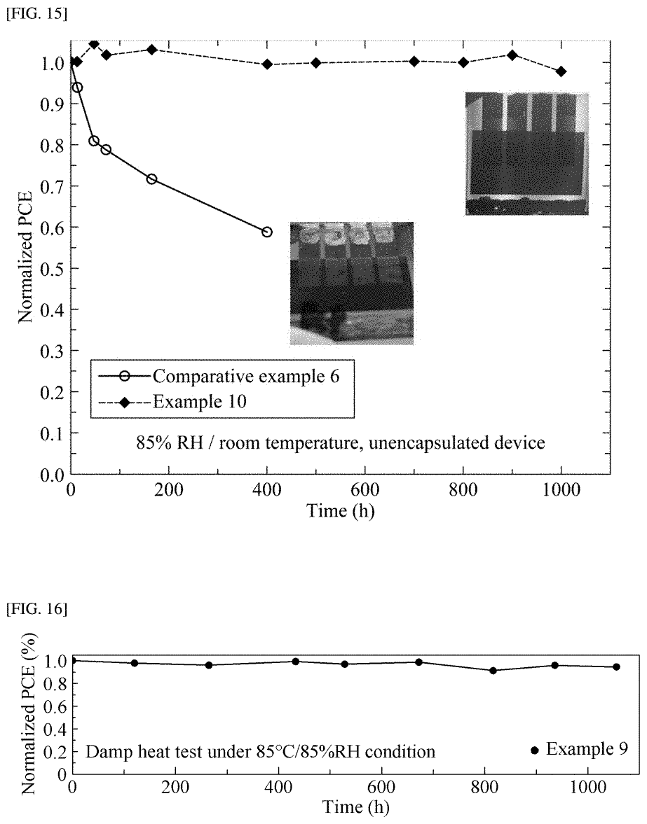

In addition, FIG. 16 is a graph showing solar cell efficiency depending on the moisture stability of the solar cell according to Example 9. Referring to FIG. 16, after glass encapsulation for blocking inflow of foreign substances was performed, when the solar cell according to Example 9 was placed in an 85% relative humidity condition at 85° C., the solar cell according to Example 9 retained an initial efficiency of 94% after 1,050 hours. Based on these results, it can be confirmed that, by forming the solar cell of the present disclosure without mixing of different dimensional materials (three- and two-dimensional materials), the solar cell of the present disclosure may have improved thermal stability.

According to an embodiment of the present disclosure, an independent interface can be formed without mixing of materials by transferring a compound including a perovskite precursor of a zero-, one-, or two-dimensional structure onto a compound including a perovskite precursor of a three-dimensional structure through a process of applying heat or pressure. Thereby, a solid-phase multilayer perovskite structure without damage at a contact surface can be manufactured.

According to an embodiment of the present disclosure, through a process of applying heat or pressure, the surface of a compound including a perovskite precursor of a three-dimensional structure can be modified with a compound including a perovskite precursor of a zero-, one-, or two-dimensional structure.

According to an embodiment of the present disclosure, a multilayer perovskite structure having improved light conversion efficiency and moisture stability can be manufactured, without damaging or mixing materials, using a compound including a perovskite precursor of a three-dimensional structure having excellent light conversion efficiency and a compound including a perovskite precursor of a two-dimensional structure having excellent moisture stability.

According to an embodiment of the present disclosure, by growing a compound including a perovskite precursor of a zero-, one-, or two-dimensional structure on a compound including a perovskite precursor of a three-dimensional structure and transferring the compound including a perovskite precursor of a zero-, one-, or two-dimensional structure onto the compound including a perovskite precursor of a three-dimensional structure, the reproducibility of a solid-phase multilayer perovskite structure without damage at the contact surface between a perovskite layer of a three-dimensional structure and a perovskite layer of a zero-, one-, or two-dimensional structure can be excellent.

According to an embodiment of the present disclosure, by transferring a compound including a perovskite precursor of a three-dimensional structure and a compound including a perovskite precursor of a zero-, one-, or two-dimensional structure by applying heat or pressure, a solar cell having improved open-circuit voltage can be manufactured.

Although the present disclosure has been described through limited examples and figures, the present disclosure is not intended to be limited to the examples. Those skilled in the art will appreciate that various modifications, additions, and substitutions are possible, without departing from the scope and spirit of the invention. Therefore, the scope of the present disclosure should not be limited by the embodiments, but should be determined by the following claims and equivalents to the following claims.

What is claimed is:

1. A method of manufacturing a multilayer perovskite structure, comprising:
forming a first perovskite layer using a compound comprising a first perovskite precursor on a base substrate;
forming a second perovskite layer using a compound comprising a second perovskite precursor on a donor substrate; and
laminating the first and second perovskite layers so that the first and second perovskite layers contact each other and then applying heat or pressure to form a multilayer perovskite structure.

2. The method according to claim 1, wherein the compound comprising the second perovskite precursor of the second perovskite layer is grown on the first perovskite layer to form the multilayer perovskite structure.

3. The method according to claim 1, wherein the second perovskite layer is transferred onto the first perovskite layer to form the multilayer perovskite structure.

4. The method according to claim 1, wherein the first perovskite precursor is represented by Chemical Formula 1 below:
CMX₃, [Chemical Formula 1]
wherein C is an organic cation or a metal cation, M is a divalent metal cation, and X is a monovalent anion.

5. The method according to claim 1, wherein the second perovskite precursor is represented by Chemical Formula 2 below:
(ANH₃)₂(RNH₃)ₙ₋₁MₙX₃ₙ₊₁ [Chemical Formula 2]
wherein A is an aryl group or an alkyl group, R is an organic cation or a metal cation, M is a divalent metal cation, X is a monovalent anion, and n is an integer of 1 or more.

6. The method according to claim 1, wherein, when heat or pressure is applied to the multilayer perovskite structure, the compound comprising the second perovskite precursor is grown in a horizontal direction.

7. The method according to claim 1, wherein the multilayer perovskite structure is heat-treated at a temperature of 30° C. to 120° C.

8. The method according to claim 1, wherein a pressure of 1 MPa to 100 MPa is applied to the multilayer perovskite structure.

9. The method according to claim 1, wherein heat or pressure is applied to the multilayer perovskite structure for 1 second to 24 hours.

10. The method according to claim 1, wherein a growth thickness of the compound comprising the second perovskite precursor is adjusted depending on heating temperature or heating time when the multilayer perovskite structure is heated.

11. The method according to claim 10, wherein a growth thickness of the compound comprising the second perovskite precursor is 30 nm to 150 nm.

12. A multilayer perovskite structure, comprising:
a base substrate;
a first perovskite layer formed on the base substrate and formed of a compound comprising a first perovskite precursor; and
a second perovskite layer formed on the first perovskite layer and formed of a compound comprising a second perovskite precursor,
wherein an independent interface is formed while the first and second perovskite layers are in contact with each other.

13. The multilayer perovskite structure according to claim 12, wherein the compound comprising the second perovskite precursor of the second perovskite layer is grown on the first perovskite layer to form the multilayer perovskite structure.

14. The multilayer perovskite structure according to claim 12, wherein the second perovskite layer is transferred onto the first perovskite layer to form the multilayer perovskite structure.

15. The multilayer perovskite structure according to claim 12, wherein the first perovskite layer is formed of the compound comprising the first perovskite precursor having a three-dimensional structure, and the second perovskite layer is formed of the compound comprising the second perovskite precursor having any one of zero-, one-, and two-dimensional structures.

16. The multilayer perovskite structure according to claim 12, wherein a growth thickness of the compound comprising the second perovskite precursor is 30 nm to 150 nm.

17. A solar cell, comprising:
a base substrate;
a first electrode formed on the base substrate;
a first charge transport layer formed on the first electrode;
a perovskite photoactive layer formed on the first charge transport layer;
a second charge transport layer formed on the perovskite photoactive layer; and
a second electrode formed on the second charge transport layer,
wherein the perovskite photoactive layer comprises a first perovskite layer and a second perovskite layer, and an independent interface is formed while the first and second perovskite layers are in contact with each other.

18. The solar cell according to claim 17, wherein the first perovskite layer is formed of the compound comprising the first perovskite precursor having a three-dimensional structure, and the second perovskite layer is formed of the compound comprising the second perovskite precursor having any one of zero-, one-, and two-dimensional structures.
